(19) United States
(12) Patent Application Publication
(10) Pub. No.: US 2025/0308741 A1
(43) Pub. Date: Oct. 2, 2025

(54) ORBITRONICS DEVICE HAVING ORBITAL HALL EFFECT OR INVERSE ORBITAL HALL EFFECT, AND METHOD FOR ENHANCING EFFICIENCY THEREOF

(71) Applicant: TIANGONG UNIVERSITY, Tianjin (CN)

(72) Inventors: Delin ZHANG, Tianjin (CN); Yong JIANG, Tianjin (CN); Ping WANG, Tianjin (CN); Yuhe YANG, Tianjin (CN); Wenwen MA, Tianjin (CN)

(21) Appl. No.: 19/234,839

(22) Filed: Jun. 11, 2025

Related U.S. Application Data
(63) Continuation of application No. PCT/CN2023/140031, filed on Dec. 19, 2023.

(30) Foreign Application Priority Data
Dec. 19, 2022 (CN) 202211631188.0
Dec. 19, 2022 (CN) 202211631232.8
Dec. 19, 2022 (CN) 202211631252.5

(51) Int. Cl. H01F 10/32; H10B 61/00; H10N 50/10; H10N 50/85

(52) U.S. Cl. CPC H01F 10/329; H01F 10/3254; H01F 10/3268; H10B 61/20; H10N 50/10; H10N 50/85

(57) ABSTRACT

The present disclosure provides an orbitronic device having orbital Hall effect or inverse orbital Hall effect, and method for enhancing the efficiency thereof. The orbital torque device comprises: a ferromagnetic/non-magnetic heterojunction formed by compounding a ferromagnetic layer and a non-magnetic layer as an orbital current source, wherein the ferromagnetic layer contains a ferromagnetic material, the non-magnetic layer contains a non-magnetic material with weak spin-orbit coupling, the non-magnetic layer is used as an orbital Hall channel to generate orbital current, and the orbital current enters the ferromagnetic layer, so that an orbital torque is generated through an orbital-spin conversion effect of the ferromagnetic layer to realize switching of a magnetic moment. The present disclosure can provide orbitronic device with low cost and good performance.

### CROSS-REFERENCE TO RELATED APPLICATION

This application is a continuation of International Application No. PCT/CN2023/140031, filed on Dec. 19, 2023, which claims the priorities of a Chinese patent application with an application number of CN202211631232.8 and an invention title of “Orbitronic Storage Devices Based on Orbital Torque Effect”, a Chinese patent application with an application number of CN202211631252.5 and an invention title of “Terahertz emission Source Based on Inverse Orbital Hall Effect and Preparation Method thereof”, and a Chinese patent application with an application number of CN202211631188.0 and an invention title of “Method for Enhancing Orbital Hall Effect and Inverse Orbital Hall Effect and Application”, which were all filed on Dec. 19, 2022, and the entire contents of which are incorporated herein by reference.

### TECHNICAL FIELD

The present disclosure relates to the technical field of electronic devices, and particularly to an orbital torque device based on an orbital Hall effect or orbital Hall effect/spin Hall effect or inverse orbital hall effect and a method for enhancing the efficiency of the orbital torque device.

### BACKGROUND

Spin-orbital torque memory and logic devices have attracted much attention due to their ultralow power consumption, ultrahigh speed and ultrahigh density of data storage and logic computation. Spin-orbit torque or orbital torque memory and logic devices can realize a conversion from charge current to spin current by utilizing the spin Hall effect or orbital Hall effect or the combination between spin Hall effect and orbital Hall effect from a spin/orbital Hall materials, and the spin current enters a ferromagnetic (FM) layer to generate the spin-orbit torque or orbital torque, thus realizing the manipulation of a magnetic moment of the ferromagnetic layer. Therefore, the efficient current-induced spin-orbit torque or orbital torque or both torques is of great significance to the development of the spin-orbitronic storage and logic devices.

In the past decades, much attention has been paid to the study of the spin-orbit torque (SOT), which uses the spin Hall effect (SHE) to realize the conversion from charge current to spin current, and the spin current has a great advantage of no Joule heat dissipation compared with the charge current. The spin Hall effect has been applied in many materials, such as tungsten, tantalum, platinum and other heavy metals, as well as topological quantum materials (e.g., Bi₂Se₃, Bi₂Te₃, WTe₂ and Pt₃Sn), but the spin Hall effect of these materials as spin sources depends on the strong spin-orbit coupling (SOC) effect of the materials themselves. The strong spin-orbit coupling in heavy metals or topological quantum materials serving as a spin source is required to generate spin current and an induced spin-orbit torque to manipulate the magnetic moment of the adjacent ferromagnetic layer. However, the heavy metal elements or the topological quantum materials have issues in practical device applications: the heavy metal materials are usually expensive and have relatively small spin Hall angle; the difficulty of the fabrication process of the topological quantum materials makes it not best choice for the spin-orbit torque devices. Therefore, the use of the heavy metals or the topological quantum materials limits the choice of spin source materials.

Recently, based on theoretical prediction and experimental results, it has been proposed to generate orbital current by using an electric field, i.e., orbital Hall effect (OHE), so that the orbital Hall effect attracts considerable attention. The orbital Hall effect is independent of the strong spin-orbit coupling effect of the materials. Similar to the spin Hall effect which converts the charge current into the spin current, the orbital Hall effect converts the charge current into the orbital current in the orbital Hall materials, which carries the orbital angular momentum like the spin current carrying the spin angular momentum, and the orbital current flows into a ferromagnetic layer and is converted into the spin current due to the spin-orbit coupling of the ferromagnetic layer, which can generate a torque to manipulate the magnetic moment of the ferromagnetic layer. However, because the orbital Hall effect is independent of the strong spin-orbit coupling effect, it can be realized in weak spin-orbit coupling materials such as light metals and alloys, oxides thereof, nitrides thereof, and two-dimensional materials thereof. Therefore, compared with the spin Hall effect, the orbital Hall effect has great advantages.

Compared with the spin Hall effect, the orbital Hall effect has obvious characteristics. Firstly, the orbital Hall effect originates from the orbital texture in momentum space, so the orbital Hall effect generally exists in multi-orbit systems regardless of the magnitude of the spin-orbit coupling. Secondly, theoretical calculations show that the orbital Hall conductivity is much larger than the spin Hall conductivity in many materials, which indicates that the orbital torque caused by the orbital Hall effect can be larger than the spin-orbit torque caused by the spin Hall effect, and can improve the spin torque efficiency of spin-orbitronic devices.

However, how to improve the orbital torque efficiency to prepare a high-performance orbitronic device with a high orbital torque efficiency, and how to prepare a high-performance orbital torque device which is of low cost, not easy to be disturbed by magnetic fields, and without field assistance, are issues having been studied but not yet solved.

### SUMMARY

In view of the above content, the embodiments of the present disclosure provide an orbital torque device based on an orbital Hall effect or an inverse orbital Hall effect, a method for realizing an orbital torque switching of the magnetic moment back and forth with/without external magnetic field, and a method for enhancing the efficiency of an orbital torque device.

In an aspect of the present disclosure, there is provided an orbital torque device based on an orbital Hall effect, comprising a ferromagnetic/non-magnetic heterojunction formed by compounding a ferromagnetic layer and a non-magnetic layer as an orbital current source, wherein the ferromagnetic layer contains a ferromagnetic material, the non-magnetic layer contains a non-magnetic material with weak spin-orbit coupling, wherein the non-magnetic layer is used as an orbital Hall channel to generate orbital current, and the orbital current enters the ferromagnetic layer, so that an orbital torque is generated through an orbital-spin conversion effect of the ferromagnetic layer to realize switching of a magnetic moment.

The present disclosure further provides an orbitronic device based on an inverse orbital Hall effect and a method for enhancing the efficiency thereof. An example of the orbitronic device is an orbitronic terahertz device.

In an embodiment of the present disclosure, the orbital torque device based on an orbital Hall effect further comprises: a substrate, on which the ferromagnetic/non-magnetic heterojunction is prepared; wherein the non-magnetic layer as the orbital current source is light metal material, the ferromagnetic layer comprises a ferromagnetic multi-film layer formed by multiple material layers, a ferromagnetic single-film layer formed by one or more materials or a two-dimensional ferromagnetic material layer, and the ferromagnetic layer has a large orbit-spin conversion coefficient.

In an embodiment of the present disclosure, the orbital torque device is sequentially provided with a monocrystalline substrate, a non-magnetic layer, a ferromagnetic layer and a protective layer from bottom to top, and then an orbital torque heterojunction device and an orbital Hall nano oscillator device are manufactured by micro-nanofabrication process.

In an embodiment of the present disclosure, the orbital torque device is sequentially provided with a monocrystalline substrate, a non-magnetic layer, a ferromagnetic free layer, an insulating barrier layer, a ferromagnetic pinning lay and a protective layer from bottom to top, and an orbital torque magnetic tunnel junction device is manufactured by micro-nanofabrication process.

In an embodiment of the present disclosure, the material of the non-magnetic layer includes one or more of Zr, Ti, Al, Ru, V, Cr, Cu and Mn;
the ferromagnetic single-film layer formed by one or more materials is a CoFeB layer, a Co layer, a Ni layer, a CoNi alloy layer, a CoPt alloy layer, a CoGd alloy layer, a CoTb alloy layer, a Mn₃Sn alloy layer, a Mn₃Ge alloy layer, a Mn₃Ga alloy layer, a FePd alloy layer, a FePt alloy layer or a CoPd alloy layer;
the multi-film layer formed by the multiple material layers is a multi-film layer of CoFeB/Gd/CoFeB, a multi-film layer composed of one or more Co/Pt double-film layers, a multi-film layer composed of one or more Co/Gd double-film layers, a multi-film layer composed of one or more Co/Tb double-film layers or a multi-film layer composed of one or more Co/Ni double-film layers; wherein, the multi-film layer of CoFeB/Gd/CoFeB is composed of a CoFeB layer, a Gd layer and a CoFeB layer; the Co/Pt double-film layer is composed of a Co layer and a Pt layer; the Co/Gd double-film layer is composed of a Co layer and a Gd layer; the Co/Tb double-film layer is composed of a Co layer and a Tb layer; and the Co/Ni double-film layer is composed of a Co layer and a Ni layer;
the two-dimensional ferromagnetic material is MnBi₂Te₄, Fe₃GeTe₂, Cr₂Ge₂Te₆, Fe₅GeTe₂ or Fe₃GaTe₂.

In some embodiments of the present disclosure, the non-magnetic layer is prepared by a magnetron sputtering process; when the ferromagnetic layer is a single-film layer or a multi-film layer, each of the film layers is prepared by a magnetron sputtering process; when the ferromagnetic layer is a two-dimensional ferromagnetic material, the two-dimensional ferromagnetic material is prepared by a magnetron sputtering process, CVD/CVT or mechanical exfoliation.

In an embodiment of the present disclosure, the orbital torque device base on the orbital Hall effect is an orbital torque electronic storage device.

In another aspect of the present disclosure, there is provided an orbital torque device, comprising: a substrate; and a ferromagnetic/non-magnetic heterojunction prepared on the substrate, and containing a ferromagnetic layer and a non-magnetic layer as an orbital current source; wherein the non-magnetic layer as the orbital current source is made of light metal, the ferromagnetic layer comprises a ferromagnetic multi-film layer formed by multiple material layers, a ferromagnetic single-film layer formed by a plurality of materials or a two-dimensional ferromagnetic material layer, and the ferromagnetic layer has a large orbit-spin conversion coefficient, i.e., has an orbit-spin conversion coefficient larger than a preset value.

In some embodiments of the present disclosure, the orbital torque device is a field-free orbital torque device based on an orbital Hall effect; the field-free orbital torque device comprises: a monocrystalline substrate; an orbital torque antiferromagnetic layer formed on the monocrystalline substrate; and a first ferromagnetic layer formed on the orbital torque antiferromagnetic layer; wherein the orbital torque antiferromagnetic layer is an antiferromagnetic alloy layer containing an antiferromagnetic layer, or a light metal material or a two-dimensional antiferromagnetic layer, the first ferromagnetic layer has perpendicular magnetic anisotropy, the orbital torque antiferromagnetic layer and the first ferromagnetic layer form an orbital torque antiferromagnetic layer/ferromagnetic layer heterojunction, and the orbital torque antiferromagnetic layer is used to pin the first ferromagnetic layer to tilt the magnetic moment, and is used as an orbital Hall channel to convert a charge current into an orbital current, and then the orbital current is converted into a spin current in the first ferromagnetic layer, so that the spin current exerts torque on the first ferromagnetic layer with perpendicular magnetic anisotropy to realize field-free orbital torque switching of the magnetic moment.

In some embodiments of the present disclosure, the field-free orbital torque device is an orbital torque magnetic tunnel junction device; the first ferromagnetic layer is used as a ferromagnetic free layer; the field-free orbital torque device and orbital torque magnetic tunnel junction device further comprises: an insulating barrier layer formed on the first ferromagnetic layer; and a second ferromagnetic layer formed on the insulating barrier layer and used as a ferromagnetic pinning layer having perpendicular magnetic anisotropy; the ferromagnetic free layer, the insulating barrier layer and the ferromagnetic pinning layer form the orbital torque magnetic tunnel junction with a sandwich structure.

In some embodiments of the present disclosure, the orbital Hall channel comprises Zr, Al, Ti, Mn, Ru, V, Cr, Cu and/or other orbital Hall channel with similar characteristics, or an antiferromagnetic light metal alloy layer such as FeMn or FeCr or FeV or Mn₃Sn or Mn₃Ge or Mn₃Ga or [Fe/Mn]ₙ or [Fe/Cr]ₙ or [Fe/V]ₙ formed by ferromagnetic metals and light metals, or a two-dimensional antiferromagnetic layer such as MnPS₃, NiPS₃ or FePS₃, or an orbital torque channel layer with similar properties.

In some embodiments of the present disclosure, the orbital torque device further comprises a protective layer prepared on the ferromagnetic/non-magnetic heterojunction.

In another aspect of the present disclosure, there is further provided a method for realizing a field-free orbital torque magnetic moment in an orbital torque device, the method comprising the steps of: causing charge current to transversely pass through the orbital torque antiferromagnetic layer, so as to generate orbital current through an orbital Hall effect generated by an antiferromagnetic material in the orbital torque antiferromagnetic layer; tilting a magnetic moment of the first ferromagnetic layer through a pinning effect of the antiferromagnetic layer on the first ferromagnetic layer without applying an external magnetic field, converting the orbital current into spin current through the first ferromagnetic layer, and generating a torque action on the magnetic moment of the first ferromagnetic layer having perpendicular magnetic anisotropy by the spin current, thereby realizing a field-free orbital torque switching.

There is provided a field-free orbital torque device based on an orbital Hall effect, the field-free orbital torque device comprises: a monocrystalline substrate; an orbital torque antiferromagnetic layer formed on the monocrystalline substrate; and a first ferromagnetic layer formed on the orbital torque antiferromagnetic layer; wherein the orbital torque antiferromagnetic layer is an antiferromagnetic alloy layer containing a light metal material or a two-dimensional antiferromagnetic layer, the first ferromagnetic layer has perpendicular magnetic anisotropy, the orbital torque antiferromagnetic layer and the first ferromagnetic layer form an orbital torque antiferromagnetic layer/ferromagnetic layer heterojunction, and the orbital torque antiferromagnetic layer is used to pin the first ferromagnetic layer to tilt the magnetic moment, and is used as an orbital Hall channel to convert a charge current into an orbital current, and then the orbital current is converted into a spin current through the first ferromagnetic layer, so that the spin current exerts orbital torque on the first ferromagnetic layer with perpendicular magnetic anisotropy to realize field-free orbital torque switching of the magnetic moment.

In some embodiments of the present disclosure, the orbital torque device is a field-free orbital torque device and orbital torque magnetic tunnel junction device; the first ferromagnetic layer is used as a ferromagnetic free layer; and the orbital torque magnetic tunnel junction device further comprises: an insulating barrier layer formed on the first ferromagnetic layer; and a second ferromagnetic layer formed on the insulating barrier layer and used as a ferromagnetic pinning layer having perpendicular magnetic anisotropy; the ferromagnetic free layer, the insulating barrier layer and the ferromagnetic pinning layer form the orbital torque magnetic tunnel junction with a sandwich structure.

In some embodiments of the present disclosure, the field-free orbital torque device further comprises a protective layer formed on the magnetic tunnel junction.

In some embodiments of the present disclosure, the first ferromagnetic layer is one of a multi-film layer composed of one or more Co/Pt double-film layers, a multi-film layer composed of one or more Co/Ni double-film layers, a multi-film layer composed of one or more Co/Gd double-film layers, a multi-film layer composed of one or more Co/Tb double-film layers, a multi-film layer of CoFeB/Gd/CoFeB, a CoNi alloy layer, a CoPt alloy layer, a Mn₃Sn alloy layer, a Mn₃Ge layer, a Mn₃Ga alloy layer, a CoGd alloy layer, and a CoTb alloy layer, or a two-dimensional magnetic film material such as MnBi₂Te₄, Fe₃GeTe₂, Cr₂Ge₂Te₆, Fe₅GeTe₂ or Fe₃GaTe₂, or a magnetic film material with similar characteristics; wherein the Co/Pt double-film layer is composed of a Co layer and a Pt layer; the Co/Ni double-film layer is composed of a Co layer and a Ni layer; the multi-film layer of CoFeB/Gd/CoFeB is composed of a CoFeB layer, a Gd layer and a CoFeB layer, the Co/Gd double-film layer is composed of a Co layer and a Gd layer, and the Co/Tb double-film layer is composed of a Co layer and a Tb layer;

In some embodiments of the present disclosure, the second ferromagnetic layer is one of a multi-film layer composed of one or more Co/Pt double-film layers, a multi-film layer composed of one or more Co/Ni double-film layers, a multi-film layer composed of one or more Co/Gd double-film layers, a multi-film layer composed of one or more Co/Tb double-film layers, a multi-film layer of CoFeB/Gd/CoFeB, a CoNi alloy layer, a CoPt alloy layer, a Mn₃Sn alloy layer, a Mn₃Ge layer, a Mn₃Ga alloy layer, a CoGd alloy layer, and a CoTb alloy layer, or a two-dimensional magnetic film material such as MnBi₂Te₄, Fe₃GeTe₂, Cr₂Ge₂Te₆, Fe₅GeTe₂ or Fe₃GaTe₂, or a magnetic film material with similar characteristics; wherein the Co/Pt double-film layer is composed of a Co layer and a Pt layer; the Co/Ni double-film layer is composed of a Co layer and a Ni layer; the multi-film layer of CoFeB/Gd/CoFeB is composed of a CoFeB layer, a Gd layer and a CoFeB layer, the Co/Gd double-film layer is composed of a Co layer and a Gd layer, and the Co/Tb double-film layer is composed of a Co layer and a Tb layer.

In some embodiments of the present disclosure, the antiferromagnetic alloy layer is an antiferromagnetic light metal alloy layer formed by a ferromagnetic metal and a light metal; the antiferromagnetic light metal alloy layer includes FeMn, FeCr, FeV, or Mn₃Sn or Mn₃Ge or Mn₃Ga, [Fe/Mn]ₙ or [Fe/Cr]ₙ or [Fe/V]ₙ; and the two-dimensional antiferromagnetic layer includes MnPS₃, NiPS₃ or FePS₃; the insulating barrier layer is MgO or TiO₂ or BN or two-dimensional semiconductor; and the protective layer is one or more films made of MgO, Ta, W or SiO₂.

In some embodiments of the present disclosure, the orbital torque device is an orbital Hall nano oscillator; the non-magnetic layer is a light metal, oxide of the light metal, nitride of the light metal, an antiferromagnetic light metal alloy layer formed by a ferromagnetic metal and a light metal, or a two-dimensional antiferromagnetic layer. The light metal includes one or more of Zr, Al, Ti, Mn, Ru, V, Cr, and Cu.

In another aspect of the present disclosure, there is further provided a method for enhancing efficiency of an orbitronic device based on orbital Hall effect or inverse orbital Hall effect, comprising: preparing, on a substrate, a ferromagnetic/non-magnetic heterojunction formed by compounding a ferromagnetic layer and a non-magnetic layer as an orbital current source, wherein the ferromagnetic layer contains a ferromagnetic material, the non-magnetic layer contains a non-magnetic material with weak spin-orbit coupling; and constructing the orbitronic device based on orbital Hall effect or inverse orbital Hall effect of the non-magnetic material with weak spin-orbit coupling; wherein the non-magnetic layer as the orbital current source is made of light metal, and the ferromagnetic layer comprises a multi-film layer formed by multiple material layers, a single-film layer formed by a plurality of materials or a two-dimensional ferromagnetic material layer, and the ferromagnetic layer has an orbital-spin conversion coefficient larger than a preset value.

In another aspect of the present disclosure, there is further provided an orbitronic device based on an inverse orbital Hall effect, comprising a ferromagnetic/non-magnetic heterojunction formed by compounding a ferromagnetic layer and a non-magnetic layer as an orbital current source, wherein the ferromagnetic layer contains a ferromagnetic material, the non-magnetic layer contains a non-magnetic material with weak spin-orbit coupling, and the non-magnetic material is a light metal; and the terahertz emission source is constructed based on the inverse orbital Hall effect of the ferromagnetic/non-magnetic heterojunction.

In some embodiments of the present disclosure, the orbitronic device based on the inverse orbital Hall effect is a terahertz emission source; the terahertz emission source comprises a monocrystalline substrate, a ferromagnetic material layer, a light metal layer and a protective layer which are sequentially stacked; the ferromagnetic material layer is one or more of Co, Fe, Ni, NiFe and CoFeB; and the light metal layer is one or more of Al, Ti, V, Cr, Mn, Cu, oxides thereof and nitrides thereof.

In another aspect of the present disclosure, there is further provided a method for enhancing efficiency of an orbitronic device based on orbital Hall effect or inverse orbital Hall effect, comprising: preparing, on a substrate, a ferromagnetic/non-magnetic heterojunction formed by compounding a ferromagnetic layer and a non-magnetic layer as an orbital current source, wherein the ferromagnetic layer contains a ferromagnetic material, the non-magnetic layer contains a non-magnetic material with weak spin-orbit coupling; and constructing the orbitronic device based on orbital Hall effect or inverse orbital Hall effect of the non-magnetic material with weak spin-orbit coupling; wherein the non-magnetic layer as the orbital current source is made of light metal, and the ferromagnetic layer comprises a multi-film layer formed by multiple material layers, a single-film layer formed by a plurality of materials or a two-dimensional ferromagnetic material layer, and the ferromagnetic layer has an orbital-spin conversion coefficient larger than a preset value.

In the method for enhancing efficiency of an orbitronic device based on orbital Hall effect or inverse orbital Hall effect, a strong spin-orbit coupling of heavy metals is utilized to realize a conversion from spin current to orbital current, enhance the orbital Hall effect and the inverse orbital Hall effect, and improve the efficiency of the orbital Hall effect or the inverse orbital Hall effect.

In the orbital torque device according to the embodiment of the present disclosure, the strong spin-orbit coupling materials is used to replace the non-magnetic material having weak spin-orbit coupling to generate an orbital torque to realize the switching or precession of the magnetic moment, thereby realizing the information storage with a low cost, a high density, a high speed and a low power consumption.

The orbital torque device (or called as orbitronic device) based on the orbital Hall effect provided by the present disclosure uses a light metal as the material of the orbital current source, thus lifting the restriction on the selection of the material of the orbital current source. Moreover, a ferromagnetic layer with a large orbital-spin conversion coefficient is selected to enhance the orbital torque to realize an orbital torque switching of the magnetic moment, so that the prepared orbitronic device is of not only low cost but also good performance. In addition, based on the orbital Hall channel, a field-free orbital torque device can be realized.

Further, the field-free orbital torque device (e.g., the orbital torque heterojunction and orbital torque magnetic tunnel junction device) based on the orbital torque antiferromagnetic material, the orbitronic device and the method for realizing the field-free orbital torque in the present disclosure use an orbital torque antiferromagnetic material prepared with a light metal alloy material combined with a material with a strong spin-orbit coupling such as a heavy metal or a topological insulator as an orbital current source to convert charge current to orbital current, which is converted into spin current in the ferromagnetic layer with a tilted magnetic moment after antiferromagnetic pinning, thereby realizing a field-free switching or precession of the magnetic moment.

Because the used light metal alloy achieves a low cost, the field-free orbital torque switching can realize even without external magnetic field, so that the power consumption is lower, and there is no interference of external magnetic field. Therefore, the storage density can be made higher when the orbital torque magnetic tunnel junction is used in a spin-orbital torque electron storage and logic devices. In addition, since the orbital torque antiferromagnetic material can obtain a smaller switching current density and realize large orbital torque efficiency, a low-energy writing can be achieved.

Additional advantages, objectives and features of the present disclosure will be set forth in part in the following description, and in part will become apparent to those skilled in the art upon examination of the following description, or may be learned by practice of the present disclosure. The objectives and other advantages of the present disclosure can be realized and attained through the structures particularly pointed out in the specification and the drawings.

Those skilled in the art will appreciate that the objectives and advantages that can be achieved by the present disclosure are not limited to those specifically described above, and the above and other objectives that can be achieved by the present disclosure will be more clearly understood from the following detailed description.

### BRIEF DESCRIPTION OF THE DRAWINGS

The drawings illustrated here are intended to provide a further understanding of the present disclosure and constitute a part thereof, rather than being limitations thereto. In the drawings:

FIG. 1 illustrates a schematic diagram of an orbital Hall effect.

FIG. 2 illustrates a structural design diagram of an orbital torque heterojunction device according to an embodiment of the present disclosure.

FIG. 3 illustrates a schematic diagram of a measurement of an orbital torque heterojunction device according to an embodiment of the present disclosure.

FIG. 4A illustrates a structural design diagram of an orbital torque magnetic tunnel junction device according to an embodiment of the present disclosure.

FIG. 4B illustrates a structural design diagram of an orbital torque magnetic tunnel junction device according to an embodiment of the present disclosure.

FIG. 4C illustrates a structural design diagram of an orbital torque magnetic tunnel junction device according to an embodiment of the present disclosure.

FIG. 5 illustrates a structural design diagram of an orbital Hall nano oscillator device according to an embodiment of the present disclosure.

FIG. 6 illustrates a structural diagram of an orbitronic device based on an orbital Hall effect according to an embodiment of the present disclosure.

FIG. 7 illustrates a structural diagram of a Zr(5)/CoFeB(0.8)/Gd(1.2)/CoFeB(1.1)/MgO(2)/W(2) device according to an embodiment of the present disclosure.

FIG. 8 illustrates a diagram of R_{AHE}-H and R_{AHE}-J loops corresponding to the structure illustrated in FIG. 7.

FIG. 9 illustrates a structural diagram of Zr(10)/[Co(0.6)/Pt(1.5)]₂ according to an embodiment of the present disclosure.

FIG. 10 illustrates a diagram of R_{AHE}-H and R_{AHE}-J loops corresponding to the structure illustrated in FIG. 9.

FIG. 11 illustrates a structural diagram of Zr(10)/Fe₃GeTe₂(10)/MgO(2)/W(2) according to an embodiment of the present disclosure.

FIG. 12 illustrates a design and measurement diagram of Al₂O₃/Co/Ti/MgO heterojunction structure.

FIG. 13 illustrates a schematic diagram for distinguishing an orbital Hall effect in a composite heterojunction of a ferromagnetic material Co and a weak spin-orbit coupling material Ti.

FIG. 14 illustrates a terahertz emission spectrogram of Al₂O₃/Co/Ti/MgO heterojunction.

FIG. 15 illustrates a design and measurement diagram of Al₂O₃/Co/Mn/MgO heterojunction structure.

FIG. 16 illustrates a design and measurement diagram of Al₂O₃/Co/W/Ti/MgO heterojunction structure.

FIG. 17 illustrates a schematic diagram of a mechanism for enhancing an inverse orbital Hall effect of Al₂O₃/Co/W/Ti/MgO heterojunction.

FIG. 18 illustrates a terahertz emission spectrogram of Al₂O₃/Co/Ti/MgO, Al₂O₃/Co/W/MgO and Al₂O₃/Co/W/Ti/MgO heterojunctions.

FIG. 19 illustrates a design and measurement diagram of Al₂O₃/Co/W/Mn/MgO heterojunction structure.

FIG. 20 illustrates a structural diagram of an orbital torque heterojunction device according to an embodiment of the present disclosure.

FIG. 21 illustrates a schematic diagram of a field-free orbital torque reversal switching mechanism of an orbital torque heterojunction device according to an embodiment of the present disclosure.

FIG. 22 illustrates a schematic diagram of field-free orbital torque switching and an orbital torque device according to an embodiment of the present disclosure.

FIG. 23 illustrates an example of perpendicular magnetic anisotropy detection results of a ferromagnetic vertical structure layer according to an embodiment of the present disclosure.

FIG. 24 illustrates a structural design diagram of an orbital torque magnetic tunnel junction device according to an embodiment of the present disclosure.

FIG. 25 illustrates a schematic diagram of a field-free orbital torque switching mechanism of an orbital torque magnetic tunnel junction device according to an embodiment of the present disclosure.

### DETAILED DESCRIPTION OF THE PREFERRED EMBODIMENTS

To make the objective, technical solution and advantages of the present disclosure clearer, the present disclosure will be further explained in detail below in conjunction with the embodiments and the drawings. Here, the exemplary embodiments of the present disclosure and the description thereof are used to explain the present disclosure, rather than being limitations thereto.

Here, it should also be noted that, in order to avoid the present disclosure from being obscured by unnecessary details, only the structures and/or processing steps closely related to the solution according to the present disclosure are illustrated in the drawings, and other details not much related to the present disclosure are omitted.

It should be emphasized that the term “comprise/include” when used herein refers to the presence of features, elements, steps or components, but does not exclude the presence or addition of one or more other features, elements, steps or components.

Here, it should also be noted that unless otherwise specified, the term “connection” may refer not only to a direct connection, but also to an indirect connection with an intermediate.

Since the orbital Hall effect originates from the orbital texture in momentum space, there is no need for the spin-orbit coupling (SOC) of the orbital Hall materials itself. Therefore, in the present disclosure, the inventors select a light metal material instead of a heavy metal material as the orbital current source to reduce the device manufacturing cost.

According to the present disclosure, a heterojunction is formed by compounding a material having weak spin-orbit coupling and a ferromagnetic material, which can convert the charge current into the orbital current in the material having weak spin-orbit coupling based on the orbital Hall effect, and then the orbital current exerts orbital torque on the ferromagnetic layer to realize the conversion from the orbital current into the spin current, so that an orbital torque is generated to reverse the magnetic moment of the ferromagnetic layer, and a conversion of the charge current-orbital current-spin current is realized, thereby implementing a storage device based on the orbital torque, which effectively solves the problems of high cost and difficult for preparation of the orbital torque device in the prior art. The orbitronic devices (also referred to as orbital torque devices) prepared in the present disclosure may include electronic devices based on orbital Hall effect, such as orbital torque heterojunction device (e.g., orbital torque electronic storage devices), orbital torque magnetic tunnel junction devices and orbital Hall nano oscillator devices. The orbital torque devices of the present disclosure may also include electronic devices based on inverse orbital Hall effect, such as orbitronic terahertz emission sources.

### Embodiment 1: Hardware Design and Preparation Method of Orbital Torque Heterojunction Device

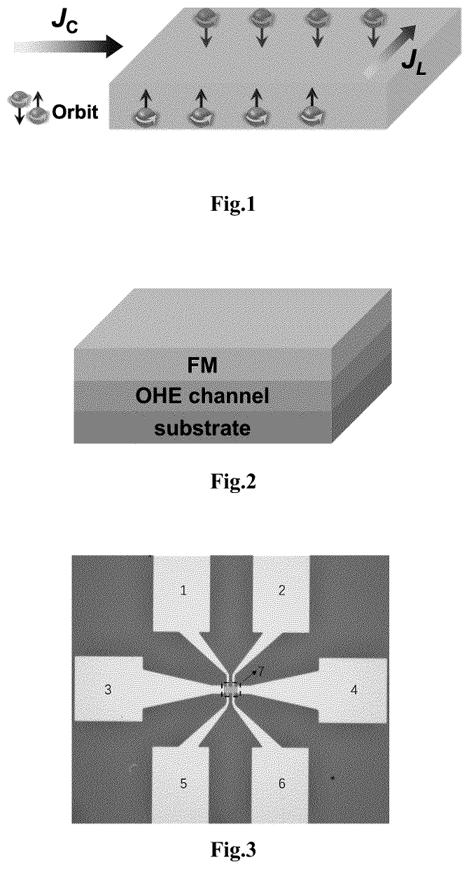

As illustrated in FIG. 1, a schematic diagram of an orbital Hall effect is given, and a charge current Jc is converted into orbital current J_{L} through the orbital Hall effect in a weak spin-orbit coupling material.

As illustrated in FIGS. 2 and 3, structural design and device measurement diagrams of an orbital torque heterojunction device are given, wherein a ferromagnetic/non-magnetic heterojunction is formed by compounding a ferromagnetic material and a non-magnetic material with weak spin-orbit coupling, and orbital current generated by the non-magnetic material with weak spin-orbit coupling as an orbital Hall channel enters the ferromagnetic material to generate an orbital torque to realize the switching of a magnetic moment. In FIG. 3, numerals 1, 2, 3, 4, 5 and 6 represent electrodes, and numeral 7 represents an orbitronic device in FIG. 7. The contact electrode is Ti (10 nm) or Pt (100 nm). Pulse current is applied in a longitudinal direction (3→4), and an anomalous Hall resistance R_{AHE} is measured in a transverse direction (1→5 or 2→6).

The hardware design concept of the orbital torque heterojunction device:
1) The orbital torque heterojunction device is sequentially provided with a monocrystalline substrate, a non-magnetic layer, a ferromagnetic layer and a protective layer (MgO, etc.) from bottom to top, and then the orbital torque heterojunction device is manufactured by micro-nano fabrication process. The non-magnetic layer may be light metal such as Zr, Al, Ti, V, Cr, Ru, Mn or Cu, oxide of the light metal, or nitride of the light metal. The ferromagnetic layer may be Co, Fe, Ni, NiFe or CoFeB, or two-dimensional magnetic film material, such as MnBi₂Te₄, Fe₃GeTe₂, Cr₂Ge₂Te₆, Fe₅GeTe₂ or Fe₃GaTe₂, or other magnetic materials having similar properties, or the like.
2) The non-magnetic material having weak spin-orbit coupling is used as the orbital Hall channel to convert the charge current into the orbital current, which enters the ferromagnetic material to generate the orbital torque to realize the switching of the magnetic moment, so as to implement the electronic storage device or the like based on the orbital torque. On the one hand, the dissipation of Joule heat is effectively prevented, and on the other hand, the dependence on precious metals is avoided.

### The Preparation Method of Exemplary Orbital Torque Heterojunction Device

A magnetron sputtering method is used to sequentially dispose a non-magnetic layer, a ferromagnetic layer and a protective layer on a monocrystalline substrate. The ferromagnetic material targets such as Co, Fe, Ni, NiFe, CoFeB, or two-dimensional magnetic film material (such as MnBi₂Te₄, Fe₃GeTe₂, Cr₂Ge₂Te₆, Fe₅GeTe₂ or Fe₃GaTe₂), or other magnetic film materials having similar properties, and the weak spin-orbit coupling material targets such as light metals like Al, Ti, V, Cr, Mn or Cu are selected, and the necessary process parameters are adjusted to realize a film formation, wherein a thickness of a prepared light metal layer is 1 to 100 nm.

The reaction parameters include: a substrate temperature (room temperature), a sputtering atmosphere (Ar gas atmosphere with pressure intensity of 2.5 to 3.0 mTorr), DC sputtering power of ferromagnetic and non-magnetic layers (30 to 50 W), MgO radio sputtering power (150 W), etc.

The ferromagnetic layer, for example, includes films of Co, Fe, Ni, NiFe, CoFeB, two-dimensional magnetic film material, such as MnBi₂Te₄, Fe₃GeTe₂, Cr₂Ge₂Te₆, Fe₅GeTe₂ or Fe₃GaTe₂, or other magnetic film materials with similar properties, or the like, and the non-magnetic layer, for example, includes light metal Al, Ti, V, Cr, Mn or Cu, oxide of the light metal, nitrides of the light metal, or an antiferromagnetic light metal alloy layer formed by ferromagnetic metal and light metal.

### Embodiment 2: Orbital Torque Magnetic Tunnel Junction (MTJ) Device and Preparation Method Thereof

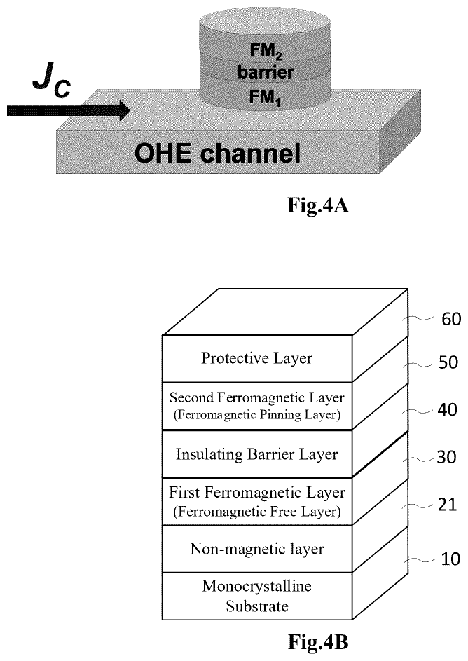

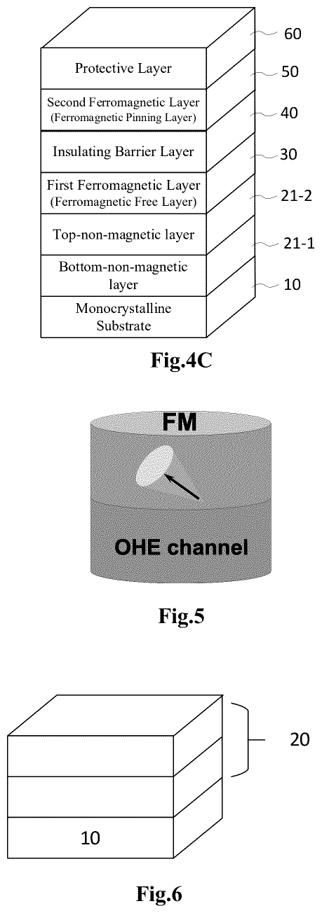

As illustrated in FIG. 4A, a structural design of an orbital torque magnetic tunnel junction device is given, wherein a ferromagnetic layer/barrier layer/ferromagnetic layer sandwich structure is prepared on a weak spin-orbit coupling material which is used as an orbital Hall channel, and the two ferromagnetic layers of the sandwich structure are used as a ferromagnetic free layer and a ferromagnetic pinning layer, respectively. The orbital current generated based on an orbital Hall effect of the weak spin-orbit coupling material enters the ferromagnetic free layer to generate an orbital torque to realize the switching of a magnetic moment.

The non-magnetic layer as the orbital Hall channel includes light metal such as Zr, Al, Ti, V, Cr, Ru, Mn and/or Cu, oxide of the light metal, or nitrides of the light metal, or an antiferromagnetic light metal alloy layer such as FeMn, FeCr, FeV, [Fe/Mn]ₙ, [Fe/Cr]ₙ or [Fe/V]ₙ formed by a ferromagnetic metal such as Fe, Co or Ni and a light metal such as Mn, Cr or V, or metal alloy layer such as Mn₃Sn, Mn₃Ge or Mn₃Ga, or a two-dimensional antiferromagnetic layer such as MnPS₃, NiPS₃ or FePS₃, or other orbital Hall channel layer with similar properties. The ferromagnetic layer includes a multi-film layer composed of one or more Co/Pt double-film layers, a multi-film layer composed of one or more Co/Ni double-film layers, a multi-film layer composed of one or more Co/Gd double-film layers, a multi-film layer composed of one or more Co/Tb double-film layers, a multi-film layer of CoFeB/Gd/CoFeB, a CoNi alloy layer, a CoPt alloy layer, a Mn₃Sn alloy layer, a Mn₃Ge layer, a Mn₃Ga alloy layer, a CoGd alloy layer, and a CoTb alloy layer, or a two-dimensional magnetic film material such as MnBi₂Te₄, Fe₃GeTe₂, Cr₂Ge₂Te₆, Fe₅GeTe₂ or Fe₃GaTe₂, or a magnetic film material with similar characteristics; wherein the Co/Pt double-film layer is composed of a Co layer and a Pt layer; the Co/Ni double-film layer is composed of a Co layer and a Ni layer; the multi-film layer of CoFeB/Gd/CoFeB is composed of a CoFeB layer, a Gd layer and a CoFeB layer, the Co/Gd double-film layer is composed of a Co layer and a Gd layer, and the Co/Tb double-film layer is composed of a Co layer and a Tb layer. The barrier layer is an MgO film.

The hardware design concept of the orbital torque magnetic tunnel junction device is that the weak spin-orbit coupling material is used as the orbital Hall channel to convert the charge current into the orbital current, which enters a ferromagnetic free layer in the sandwich structure of the magnetic tunnel junction to generate an orbital torque to realize the switching of a magnetic moment, so as to achieve a tunnel magnetoresistance effect controlled by the orbital torque, and realize the information storage with a low cost, a high density, a high speed and a low power consumption.

The preparation method of an exemplary orbital torque magnetic tunnel junction device is as follows: the orbital torque magnetic tunnel junction device is prepared by magnetron sputtering method, wherein a monocrystalline substrate 10, non-magnetic layer (light metal such as Zr, Al, Ti, V, Ru, Cr, Mn or Cu, oxide of the light metal, or nitride of the light metal) 21, a ferromagnetic free layer 30, an insulating barrier layer (MgO) 40, a ferromagnetic pinning layer 50 and a protective layer 60 are deposited sequentially from bottom to top, as shown in FIG. 4B. The ferromagnetic layer is one of a multi-film layer composed of one or more Co/Pt double-film layers, a multi-film layer composed of one or more Co/Ni double-film layers, a multi-film layer composed of one or more Co/Gd double-film layers, a multi-film layer composed of one or more Co/Tb double-film layers, a multi-film layer of CoFeB/Gd/CoFeB, a CoNi alloy layer, a CoPt alloy layer, a Mn₃Sn alloy layer, a Mn₃Ge layer, a Mn₃Ga alloy layer, a CoGd alloy layer, and a CoTb alloy layer, or a two-dimensional magnetic film material such as MnBi₂Te₄, Fe₃GeTe₂, Cr₂Ge₂Te₆, Fe₅GeTe₂ or Fe₃GaTe₂, or a magnetic film material with similar characteristics. Then the orbital torque magnetic tunnel junction device is prepared by micro-nano fabrication process.

By using the magnetron sputtering method, the targets such as ferromagnetic material CoFeB and material Gd, etc., and the targets of weak spin-orbit coupling material such as light metal Al, Ti, V, Cr, Mn or Cu are selected, and the necessary process parameters are adjusted to realize a film formation. The reaction parameters include: a substrate temperature (room temperature), a sputtering atmosphere (Ar gas atmosphere with a pressure intensity of 2.5 to 3.0 mTorr), DC sputtering power of ferromagnetic and non-magnetic layers (30 to 50 W), MgO radio frequency sputtering power (150 W), etc. The preparation thickness of the light metal layer is 1 to 100 nm.

The inventors of this application have found that by forming a heavy metal layer having strong spin-orbit coupling effect between the orbital Hall channel (such as a non-magnetic layer or antiferromagnetic layer) and the ferromagnetic layer of the heterojunction in the orbital torque device based on the orbital Hall effect, the orbital Hall effect of the orbital torque device can be enhanced, thereby the efficiency of the device can be improved. Such orbital torque devices can be orbital torque heterojunction devices, orbital torque magnetic tunnel junction devices, and orbital Hall nano-oscillator devices, etc., but the present disclosure is not limited to these devices.

For the orbital torque magnetic tunnel junction device, as shown in FIG. 4C, a strong spin-orbit coupling effect of heavy metal formed between ferromagnetic layer and the non-magnetic layer is utilized to realize a conversion from spin current to orbital current, to enhance the orbital Hall effect, and improve the efficiency of the orbital Hall effect. Compared with FIG. 4B, the non-magnetic layer structure in this embodiment is a two-layer structure, which includes a top non-magnetic layer and a bottom non-magnetic layer. The material of the bottom non-magnetic layer can be the same as that of the non-magnetic layer in FIG. 4B, while the material of the top non-magnetic layer is a heavy metal with a strong spin coupling effect, such as Pt, W, Ta, Gd and Td etc. The other structures in this embodiment can be the same as those in in FIG. 4B. In other words, as shown in FIG. 4C, an exemplary orbital torque magnetic tunnel junction device is prepared by magnetron sputtering method, wherein a monocrystalline substrate 10, a bottom non-magnetic layer (light metal such as Zr, Al, Ti, V, Ru, Cr, Mn or Cu, oxide of the light metal, or nitride of the light metal) 21-1, a top non-magnetic layer (such as Pt, W, Ta, Gd and Td etc.) 21-2, a ferromagnetic free layer 30, an insulating barrier layer 40, a ferromagnetic pinning layer 50 and a protective layer 60 are deposited sequentially from bottom to top. Compared with FIG. 4B, the orbital torque magnetic tunnel junction device has improved efficiency of the orbital Hall effect.

The method for enhancing the orbital Hall effect uses the strong spin-orbit coupling effect of heavy metals to enhance conversion from spin current to orbital current, so enhances the orbital Hall effect, and improve the efficiency of the orbital Hall effect. Thus, this method has the advantages of effectively enhancing the orbital Hall effect, with a low cost, high stability, a simple process and being beneficial to industrialization, etc.

### Embodiment 3: Orbital Hall Nano Oscillator Device and Preparation Method Thereof

As illustrated in FIG. 5, a structural design diagram of an orbital Hall nano oscillator device is given, wherein a ferromagnetic/non-magnetic heterojunction is formed by compounding a ferromagnetic material and a non-magnetic material with weak spin-orbit coupling, and the orbital current generated by the non-magnetic material with weak spin-orbit coupling as an orbital Hall channel enters the ferromagnetic material to generate an orbital torque to realize the high-frequency precession of a magnetic moment. The ferromagnetic layer includes films of NiFe or CoFeB, etc., and the non-magnetic layer includes light metal such as Zr, Al, Ti, V, Cr, Ru, Mn or Cu, oxide of the light metal, or nitride of the light metal, or an antiferromagnetic light metal alloy layer such as FeMn or FeCr or FeV or [Fe/Mn]ₙ or [Fe/Cr]ₙ or [Fe/V]ₙ formed by a ferromagnetic metal such as Fe, Co or Ni and a light metal such as Mn, Cr or V, or metal alloy layer such as Mn₃Sn, Mn₃Ge or Mn₃Ga, or a two-dimensional antiferromagnetic layer such as MnPS₃, NiPS₃ or FePS₃, or other orbital torque channel layer with similar properties.

The hardware design concept of the orbital Hall nano-oscillator device is that the non-magnetic material with weak spin-orbit coupling is used as the orbital Hall channel to convert the charge current into the orbital current, which enters a ferromagnetic material to generate an orbital/spin torque to realize the high-frequency precession of a magnetic moment, so as to achieve an electronic device based on the orbital torque. On the one hand, the dissipation of Joule heat is effectively prevented, and on the other hand, the dependence on precious metals is avoided.

The preparation method of exemplary orbital Hall nano oscillator device is as follows: monocrystalline substrate/non-magnetic layer/ferromagnetic layer/protective layer are sequentially deposited from bottom to top, and then the orbital Hall nano oscillator device is prepared by micro-nano fabrication process. The non-magnetic layer may be light metal such as Zr, Al, Ti, V, Cr, Ru, Mn or Cu, oxide of the light metal, or nitride of the light metal, or an antiferromagnetic light metal alloy layer such as FeMn or FeCr or FeV or [Fe/Mn]ₙ or [Fe/Cr]ₙ or [Fe/V]ₙ formed by a ferromagnetic metal such as Fe, Co or Ni and a light metal such as Mn, Cr or V, metal alloy layer such as Mn₃Sn, Mn₃Ge or Mn₃Ga, or a two-dimensional antiferromagnetic layer such as MnPS₃, NiPS₃ or FePS₃, or other orbital Hall channel layer with similar properties. The ferromagnetic layer may be Co, Fe, Ni, NiFe or CoFeB, two-dimensional magnetic film material, such as MnBi₂Te₄, Fe₃GeTe₂, Cr₂Ge₂Te₆, Fe₅GeTe₂ or Fe₃GaTe₂, or other magnetic film materials with similar properties, or the like The ferromagnetic layer can also be a multi-film layer composed of one or more Co/Pt double-film layers, a multi-film layer composed of one or more Co/Ni double-film layers, a multi-film layer composed of one or more Co/Gd double-film layers, a multi-film layer composed of one or more Co/Tb double-film layers, a multi-film layer of CoFeB/Gd/CoFeB, a CoNi alloy layer, a CoPt alloy layer, a Mn₃Sn alloy layer, a Mn₃Ge layer, a Mn₃Ga alloy layer, a CoGd alloy layer, and a CoTb alloy layer, or a two-dimensional magnetic film material such as MnBi₂Te₄, Fe₃GeTe₂, Cr₂Ge₂Te₆, Fe₅GeTe₂ or Fe₃GaTe₂, or a magnetic film material with similar characteristics. The protective layer may be Al₂O₃, BN, MgO, etc.

By using the magnetron sputtering method, the target material of the ferromagnetic materials such as NiFe or CoFeB and the target materials of weak spin-orbit coupling material such as light metals Zr, Al, Ti, V, Cr, Ru, Mn or Cu are selected, and the necessary process parameters are adjusted to realize a film formation. The reaction parameters include: a substrate temperature (e.g. room temperature), a sputtering atmosphere (e.g. Ar gas atmosphere with a pressure intensity of 2.5 to 3.0 mTorr), DC sputtering power of ferromagnetic and non-magnetic layers (30 to 50 W), MgO radio frequency sputtering power (150 W), etc. The preparation thickness of the light metal layer is 1 to 100 nm.

The orbital Hall effect of the orbital Hall nano-oscillator devices can also be enhanced by forming a heavy metal layer having strong spin-orbit coupling effect, such as Pt, W, Ta, Gd and Td etc., between the ferromagnetic layer and the non-magnetic layer (i.e. the orbital Hall channel) of the ferromagnetic/non-magnetic heterojunction in the orbital Hall nano-oscillator devices based on the orbital Hall effect, thereby the efficiency of the device can be improved.

In the process of implementing the present disclosure, the inventors find that the orbital-spin conversion of the ferromagnetic layer is very important for generating the orbital torque, and the orbital-spin conversion of the ferromagnetic layer can be used to realize the conversion from orbital current to spin current, thereby realizing the switching of the magnetic moment of the ferromagnetic layer. In order that the orbital torque acts on the magnetic moment of the ferromagnetic layer, the orbital angular momentum must be converted into the spin angular momentum. The magnitude and the sign of the orbital torque usually depend on the injection of the orbital current in the non-magnetic metal and the orbital-spin (L-S) conversion coefficient in the ferromagnetic layer, so finding an efficient method for the L-S conversion is the key to manipulate the magnetic moment of the ferromagnetic layer by using the orbital torque. That is, the magnitude and the sign of the orbital torque strongly depend on the orbital-spin conversion coefficient of the ferromagnetic layer, but the orbital-spin conversion coefficient of the ferromagnetic layer selected in the existing orbital torque devices is generally small, which affects the conversion efficiency from the orbital current to the spin current, resulting in low orbital torque efficiency. The orbital torque efficiency can be greatly improved by selecting a ferromagnetic layer with a large orbital-spin conversion. Therefore, in the present disclosure, based on the orbital Hall effect of light metals, the orbital torque is enhanced by selecting a ferromagnetic layer with a large orbital-spin conversion coefficient.

More specifically, in an embodiment of the present disclosure, a ferromagnetic layer with a large orbital-spin conversion coefficient is selected based on the orbital Hall effect of light metal (e.g. Zr), so as to prepare an orbitronic device (or called as an orbital torque device) based on the orbital Hall effect, such that the prepared device has enhanced orbital torque efficiency. The prepared orbitronic devices are widely used, for example, not only as orbital torque electronic storage logic devices, but also as orbital torque magnetic tunnel junction devices and orbital Hall nano oscillator devices, etc., and the present disclosure is not limited thereto.

FIG. 6 illustrates a structural diagram of an orbitronic device based on an orbital Hall effect according to an embodiment of the present disclosure. As illustrated in FIG. 6, the orbitronic device includes a substrate 10 and a ferromagnetic/non-magnetic heterojunction 20 prepared on the substrate 10.

In which, the ferromagnetic/non-magnetic heterojunction includes a ferromagnetic layer and a non-magnetic layer as an orbital current source, and the material of the non-magnetic layer (orbital current source) is light metal, such as Zr, Ti and/or Mn, but the present disclosure is not limited thereto. The ferromagnetic layer includes a ferromagnetic multi-film layer formed of multiple material layers, a ferromagnetic single-film layer formed of multiple materials or a two-dimensional ferromagnetic material layer, and the ferromagnetic layer has a large orbital-spin conversion coefficient. In the present disclosure, light metal is used as the material of the orbital current source, so that the restriction on the selection of the material of the orbital current source is lifted, and the cost of the device is greatly reduced. Because the inventors find that the orbital-spin conversion coefficient of the ferromagnetic layer is closely related to the magnitude and the sign of the orbital torque, the present disclosure enhances the orbital torque by selecting a ferromagnetic layer with a large orbital-spin conversion coefficient, so as to realize enhanced efficiency of the switching of the orbital torque. The orbitronic device proposed in the present disclosure has not only a low cost but also a good performance. The orbital-spin conversion coefficient (η) describes a spin accumulation converted by the orbital current generated by the orbital current source through the ferromagnetic layer, and the magnitude thereof is directly proportional to the magnitude of <L·S> of the ferromagnetic layer. That is, the orbital-spin conversion coefficient increases as the atomic number increases. The terahertz experimental results of heterojunctions Ti/Co and Mn/Co show that Co can realize the orbital current-spin current conversion. In addition, the theoretical calculation shows that the conversion coefficient of Co is 2.91×10⁻². Therefore, the orbital-spin conversion coefficient≥2.91×10⁻² is usually called a large orbital-spin conversion coefficient. In the binary alloy of Co, η of one element is greater than the conversion coefficient of Co, and η of the alloy is approximately equal to the average value of the conversion coefficients of two separate metal elements, so the conversion coefficient of Co alloy is greater than that of Co alone. The ferromagnetic multilayer film contains elements Gd, Tb, Pt and Ni with conversion coefficients greater than that of Co, so the conversion coefficient of the ferromagnetic multilayer film is greater than that of Co; and the two-dimensional ferromagnetic material contains element Te with a conversion coefficient greater than that of Co, so the conversion coefficient of the two-dimensional ferromagnetic material is greater than that of Co. The large orbital-spin conversion coefficient of the ferromagnetic layer can be reflected by the magnitude of the current density in the magnetic moment switching test.

In the embodiment of the present disclosure, the ferromagnetic layer is a single-film layer formed by multiple materials with a large orbital-spin conversion coefficient, a multi-film layer formed by multiple material layers or a two-dimensional ferromagnetic material. Examples of the single-film layer formed by multiple materials are a CoFeB layer, a Co layer, a Ni layer, a CoNi alloy layer, a CoPt alloy layer, a CoGd alloy layer, or a CoTb alloy layer, a Mn₃Sn alloy layer, a Mn₃Ge alloy layer, a Mn₃Ga alloy layer, a FePd alloy layer, a FePt alloy layer or a CoPd alloy layer. In which, CoFeB stands for Co₂₀Fe₆₀B₂₀, which may also be abbreviated as CFB.

Examples of the multi-film layer formed by multiple material layers are: a multi-film layer of CoFeB/Gd/CoFeB, a multi-film layer composed of one or more Co/Pt double-film layers, a multi-film layer composed of one or more Co/Gd double-film layers, a multi-film layer composed of one or more Co/Tb double-film layers or a multi-film layer composed of one or more Co/Ni double-films; in which, the multi-film layer of CoFeB/Gd/CoFeB is composed of a CoFeB layer, a Gd layer and a CoFeB layer; the Co/Pt double-film layer is composed of a Co layer and a Pt layer; the Co/Gd double-film layer is composed of a Co layer and a Gd layer; the Co/Tb double-film layer is composed of a Co layer and a Tb layer; and the Co/Ni double-film layer is composed of a Co layer and a Ni layer.

Examples of the two-dimensional ferromagnetic material may be Fe₃GeTe₂, Cr₂Ge₂Te₆, Fe₅GeTe₂ or Fe₃GaTe₂. These two-dimensional ferromagnetic materials are only examples, and the present disclosure is not limited thereto.

In the embodiment of the present disclosure, the substrate may be a c-face Al₂O₃ substrate, i.e., c-Al₂O₃, but the present disclosure is not limited thereto, and the substrate may also be other materials, such as a Si substrate, a SiO₂ substrate and an MgO substrate.

In the orbitronic device with the above structure of the present disclosure, when current flows into the light-metal non-magnetic layer as the orbital current source, the charge current is converted into orbital current through the orbital Hall effect (OHE) of the orbital current source, the orbital current is further injected into the ferromagnetic layer with a large orbital-spin conversion coefficient, the orbital current is converted into the spin current through the strong orbital-spin conversion effect of the ferromagnetic layer, and the spin current interacts with the magnetic moment of the ferromagnetic layer through exchange coupling, thereby realizing the switching of the magnetic moment of the ferromagnetic layer.

The orbitronic device with the above structure of the present disclosure may be used for the orbitronic memory and logic device, the orbital torque magnetic tunnel junction device, the orbital Hall nano oscillator device, etc.

In some embodiments of the present disclosure, in the ferromagnetic/non-magnetic heterojunction of the orbitronic device, the non-magnetic layer (orbital current source) is closer to the substrate, and the ferromagnetic layer is located on a surface of the non-magnetic layer away from the substrate.

In some application scenarios, the orbitronic device may further include a protective layer prepared on the ferromagnetic/non-magnetic heterojunction. Preferably, the protective layer may be an MgO layer, a W layer, or a double-layered protective layer of the MgO layer and the W layer.

The following will list the structural examples, preparations, and orbital torque testing results of several orbitronic devices.

### Embodiment 4: Zr(5)/CoFeB(0.8)/Gd(1.2)/CoFeB(1.1)/MgO(2)/W(2) Orbitronic Device

As illustrated in FIG. 7, the orbitronic device includes the following film layers in sequence: Zr(5), CoFeB(0.8), Gd(1.2), CoFeB(1.1), MgO(2) and W(2). Values in the parentheses represent the thicknesses of respective film layers in nm, the thickness of the non-magnetic layer Zr is 5 nm, the thicknesses of CoFeB, Gd and CoFeB in the multi-film layer of CoFeB/Gd/CoFeB are 0.8 nm, 1.2 nm and 1.1 nm, respectively, and the thicknesses of MgO and W are both 2 nm. The substrate is c-Al₂O₃, and light metal Zr is used as the orbital current source. The three-layer film of CoFeB(0.8)/Gd(1.2)/CoFeB(1.1) is used as the ferromagnetic layer, which has good perpendicular magnetic anisotropy (PMA) and large orbital-spin conversion coefficient. The three-layer film may be abbreviated as CFB/Gd/CFB, wherein CFB stands for Co₂₀Fe₆₀B₂₀; the light metal and the ferromagnetic layer form the ferromagnetic/non-magnetic heterojunction. The magnesium oxide (MgO) layer and/or the tungsten (W) layer is used as the protective layer to protect the underlying film from oxidation.

The device in this embodiment is prepared in the following process:

An ultra-high vacuum multi-target sputtering system device is used to mount Zr, CoFeB, Gd, MgO and W targets on a plurality of sputtering target heads respectively; a c-face Al₂O₃ (c-Al₂O₃) substrate is placed on a sample rack, and appropriate process parameters are adjusted to form the films on c-Al₂O₃ respectively by magnetron sputtering. The reaction parameters may include: substrate temperature, sputtering atmosphere, and sputtering power, etc. Exemplary process parameter conditions are: the substrate temperature is room temperature; and the sputtering pressure intensity is 3 mTorr. Zr, CoFeB, Gd, MgO and W have sputtering powers of 40, 50, 50, 150 and 30 W respectively, and sputtering rates of 0.271, 0.144, 0.742, 0.049 and 0.162 Å/s respectively. By controlling the growth sequence of respective layers, the light metal Zr film is grown first, then the CoFeB/Gd/CoFeB films of the ferromagnetic layer are grown in turn, and finally the MgO layer and/or the W-layered protective layer is grown. The thicknesses of the Zr/CoFeB/Gd/CoFeB/MgO/W films are controlled to be 5, 0.8, 1.2, 1.1, 2, and 2 nm, respectively. Here, the listed process parameters (including film layer thicknesses) are only examples, and the present disclosure is not limited thereto, but these parameters may be adjusted and changed appropriately. The thickness and the proportion of the structure of each layer in the ferromagnetic layer are controlled so that the ferromagnetic layer as a whole has good perpendicular magnetic anisotropy.

### Orbital Torque Driven Magnetization Switching Test

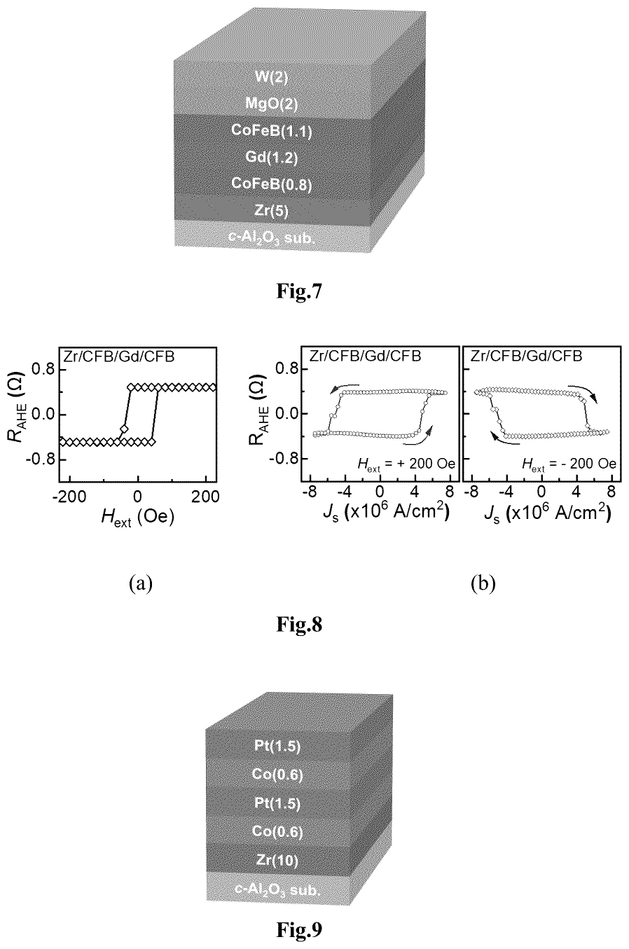

The samples are fabricated into Hall bars by standard photolithography and argon ion milling techniques, as illustrated in FIG. 3, to measure the perpendicular magnetic anisotropy and the critical switching current density. In the ferromagnetic layer, the numbers of spin-up electrons and spin-down electrons are not equal near a Fermi surface. Due to spin-dependent scattering and spin-orbit coupling, the spin-up electrons and the spin-down electrons are deflected in opposite directions when an electric field is applied, resulting in a potential difference between two ends of the ferromagnetic layer. The abnormal Hall resistance R_{AHE} is a ratio of a potential difference generated to the applied current. Regarding relationship diagrams of R_{AHE}-H and R_{AHE}-J, the relationship diagram of R_{AHE}-H shows the change trend of R_{AHE} along with the applied magnetic field, and the R_{AHE}-H curve can reflect perpendicular magnetic anisotropy of the sample structure; the relationship diagram of R_{AHE}-J shows the change trend of R_{AHE} along with the applied pulse current, and the R_{AHE} curve can reflect the critical switching current density of the sample structure; by comparing the magnitudes of R_{AHE} in R_{AHE}-H and R_{AHE}-J, the degree to which the torque generated in the light metal Zr switches the magnetic moment of the ferromagnetic layer can be reflected. R_{AHE}-H and R_{AHE}-J are measured with Keithley 2400, 2182A, and 6221A systems, and the test results are illustrated in FIG. 8. As can be seen from FIG. 8, Zr/CFB/Gd/CFB/MgO/W has good perpendicular magnetic anisotropy (PMA) with very low critical switching current density of 4.9×10⁶ A/cm², which is comparable to the critical switching current density for heavy metals to achieve the switching of the magnetic moment, and shows that Zr/CFB/Gd/CFB/MgO/W has a high orbital torque efficiency. If the ferromagnetic layer has a large orbital-spin conversion coefficient, the conversion efficiency from the orbital current to the spin current can be improved, and the orbital torque efficiency can be enhanced, thereby reducing the critical switching current density. The low critical switching current density in the test result indicates that the ferromagnetic layer has a large orbital-spin conversion coefficient, that is, the device has high orbital-torque efficiency.

In this embodiment, the light metal Zr with a high orbital Hall conductivity is selected as the orbital current source. Due to the orbital Hall effect of Zr, the charge current of Zr layer is converted into orbital current, which is injected into the ferromagnetic layer with a large orbital-spin conversion coefficient and converted into spin current, then a torque, i.e., an orbital torque, is applied to the ferromagnetic layer, thereby realizing the orbital torque for the ferromagnetic layer. That is, the light metal Zr is used as the orbital current source in the present disclosure to realize the orbitronic device with a high orbital torque efficiency.

### Embodiment 5: Zr(10)/[Co(0.6)/Pt(1.5)]₂ Orbitronic Device

As illustrated in FIG. 9, the orbitronic device includes the film layers Zr(10), and [Co(0.6)/Pt(1.5)]₂ in sequence, where values in the parentheses represent the thicknesses of respective film layers in nm, and the subscript 2 represents two Co/Pt double-film layers. The substrate is c-Al₂O₃, and the light metal Zr is used as the orbital current source. As the ferromagnetic layers, the two Co/Pt double-film layers have good perpendicular magnetic anisotropy (PMA) and a large orbital-spin conversion coefficient, and the light metal and the ferromagnetic layers form ferromagnetic/non-magnetic heterojunctions. In this embodiment, Pt is not easy to be oxidized, so the protective layer is omitted.

The device in this embodiment is prepared in the following process:

By using an ultra-high vacuum multi-target sputtering system device, Zr, Co and Pt targets are respectively mounted on a plurality of sputtering target heads; a c-face Al₂O₃ substrate is placed on a sample rack, and appropriate process parameters are adjusted to form the films on c-Al₂O₃ respectively by magnetron sputtering. The reaction parameters may include: substrate temperature, sputtering atmosphere, and sputtering power, etc. Exemplary process parameter conditions are: the substrate temperature is 300° C.; the argon flow rate is 33 sccm; and the sputtering pressure intensity is 3 mTorr. Zr, Co and Pt have sputtering powers of 40, 50 and 15 W respectively, and sputtering rates of 0.271, 0.203 and 0.171 Å/s respectively. By controlling the growth sequence of respective layers, the light metal Zr film is grown first, then the films of the ferromagnetic materials Co and Pt are grown in turn, and the films of Co and Pt are grown repeatedly to form two Co/Pt double-layer films. During the growth, the thicknesses of Zr, Co, and Pt films are controlled to be 10, 0.6, and 1.5 nm, respectively. Here, the listed process parameters are only examples, and the present disclosure is not limited thereto, but these parameters may be adjusted and changed appropriately. The thickness and the proportion of the structure of each layer in the ferromagnetic layer are controlled so that the ferromagnetic layer as a whole has good perpendicular magnetic anisotropy.

### Orbital Torque Driven Magnetization Switching Test

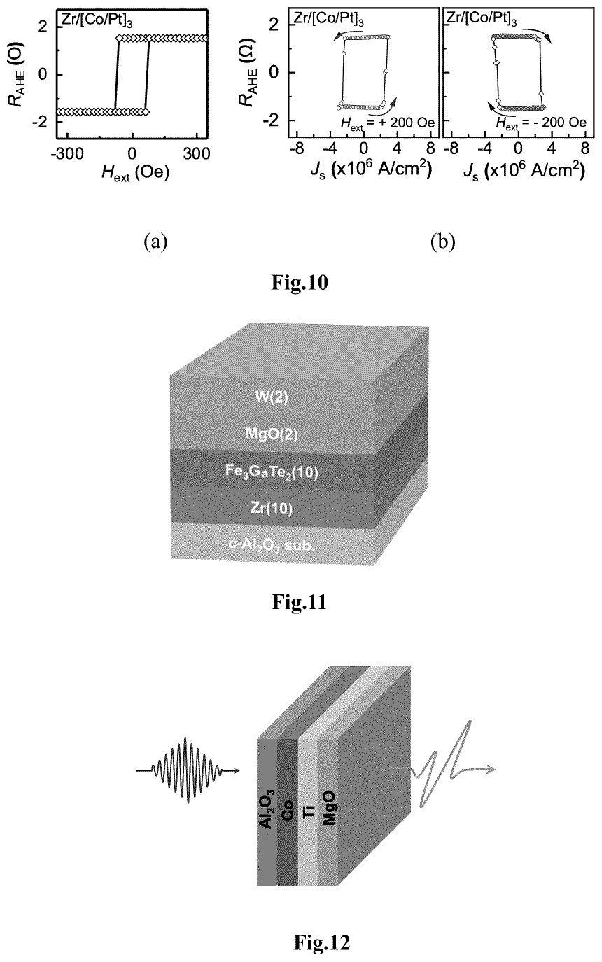

The samples are fabricated into Hall bars by standard photolithography and argon ion milling techniques, as illustrated in FIG. 3, to measure the critical switching current density. The testing results are illustrated in FIG. 10. As can be seen from FIG. 10, [Co/Pt]ₙ has good perpendicular magnetic anisotropy (PMA), and the critical switching current density is ˜2.6×10⁶ A/cm². The testing results also prove that the ferromagnetic layer has good perpendicular magnetic anisotropy and a large orbital-spin conversion coefficient, so that the device has a high orbital torque efficiency.

### Embodiment 6: Zr(10)/Fe₃GaTe₂(10)/MgO(2)/W(2) Orbitronic Device

As illustrated in FIG. 11, the orbitronic device includes the film layers Zr(10), Fe₃GaTe₂(10), MgO(2) and W(2) in sequence, where values in the parentheses represent the thicknesses of respective film layers in nm. The substrate is c-Al₂O₃, and the light metal Zr is used as the orbital current source. As the ferromagnetic layer, Fe₃GaTe₂ has good perpendicular magnetic anisotropy (PMA), and the light metal and the ferromagnetic layer form ferromagnetic/non-magnetic heterojunctions. The protective layers are a magnesium oxide (MgO) layer and a tungsten (W) layer.

The device in this embodiment is prepared in the following process:

By using an ultra-high vacuum multi-target sputtering system device, Zr, MgO and W targets are respectively mounted on a plurality of sputtering target heads; a c-face Al₂O₃ substrate is placed on a sample rack, and appropriate process parameters are adjusted to form the films on the substrate by magnetron sputtering. Firstly, a Zr film is grown by magnetron sputtering, and the thickness of the film is controlled to be 10 nm. Then, a two-dimensional ferromagnetic material Fe₃GaTe₂ (abbreviated as FGT) is prepared by dry method. On a clean c-Al₂O₃ substrate, a thin layer of FGT with a suitable shape is transferred onto the Zr film through mechanical exfoliation and an electron microscopy transfer platform. Next, the MgO film and the W film are further grown by magnetron sputtering, and the thicknesses of the two films are both controlled to be 2 nm.

The inventors still use the testing structure illustrated in FIG. 3 to carry out the orbital torque test. The measurement results also show that the ferromagnetic layer has good perpendicular magnetic anisotropy and a large orbital-spin conversion coefficient, so that the orbitronic device has a high orbital torque efficiency.

In the structure of the orbitronic device provided by the above embodiments, the non-magnetic layer is not limited to a Zr film, but may also be a Ti film or a Mn film, or an alloy layer of two or three of Zr, Ti and Mn. The thickness of each film layer is only an example, and the present disclosure is not limited thereto, but may be changed within an appropriate range. For example, the thickness of the non-magnetic layer may be 2 to 20 nm, more preferably 2 to 10 nm, and the thickness of each protective layer may be 1 to 5 nm. In Embodiment 1, the total thickness of the multi-film layer of CoFeB/Gd/CoFeB may be 2 to 5 nm, and the thickness of each layer in the multi-film layer may also be adjusted, as long as the formed CoFeB/Gd/CoFeB has good perpendicular magnetic anisotropy. In Embodiment 2, the total thickness of the Co/Pt double-film layer and the thicknesses of the Co layer and the Pt layer may all be varied. For example, the total thickness of the Co/Pt double-film layer may be 2 to 10 nm, and the thicknesses of the Co layer and the Pt layer are controlled so that the formed single or multiple Co/Pt double-film layers have good perpendicular magnetic anisotropy. In addition, the Co/Pt double-film layer may be replaced with a Co/Gd double-film layer, a Co/Tb double-film layer or a Co/Ni double-film layer, and there may be one or more double-film layers. The thickness of the two-dimensional ferromagnetic material is preferably 5 to 20 nm, more preferably 8 to 15 nm, and the two-dimensional ferromagnetic material may also be replaced with Cr₂Ge₂Te₆, Fe₅GeTe₂, Fe₃GaTe₂ or the like. In addition, in the embodiment of the present disclosure, the protective layer may be not only an MgO layer and/or a W layer, but also any other material layer not easy for oxidation, such as a SiO₂ layer or a Ta (tantalum) layer. The inventors have tested the switching of the orbital torque of the orbitronic device prepared when the ferromagnetic layer is the above listed multi-film layer, single-film layer or the two-dimensional ferromagnetic material layer, which proves that the prepared orbitronic device has good perpendicular magnetic anisotropy and a large orbital-spin conversion coefficient.

In the present disclosure, a ferromagnetic layer with a large orbital-spin conversion coefficient is used to improve the efficiency of converting the orbital current into the spin current. That is, in the embodiment of the present disclosure, the efficiency of converting the orbital current into the spin current is enhanced by selecting a ferromagnetic layer with a large orbital-spin conversion coefficient, thereby enhancing the orbital torque. In a case where a film layer with a large orbital-spin conversion coefficient is selected as the ferromagnetic layer, when the orbital current is injected into the ferromagnetic layer, the efficiency of converting the orbital current into the spin current is improved and the orbital torque efficiency is enhanced due to the large orbital-spin conversion coefficient of the ferromagnetic layer, thereby reducing the critical switching current density. The light metal is selected as the orbital current source, which reduces the cost and greatly expands the selection range of the orbital current source material.

In the embodiment of the present disclosure, the orbital torque device is based on the orbital Hall effect of the light metal with weak spin-orbit coupling, and takes the light metal as the material of the orbital current source, so that the restriction on the selection of the material of the orbital current source is lifted. The light metal replaces the heavy metal, thereby greatly reducing the cost. Moreover, in the embodiment of the present disclosure, the orbital torque is enhanced by selecting a ferromagnetic layer with a large L-S coefficient, so that the prepared orbital torque device has not only a low cost but also a good performance. The orbitronic devices prepared in the present disclosure may be used not only as spin-orbit torque memory and logic devices, orbital torque magnetic tunnel junction devices and/or orbital Hall nano oscillator devices, but also has great application prospects in the field of semiconductor technologies.

The orbital torque device of the present disclosure may also be used as a terahertz emission source based on the inverse orbital Hall effect. The orbital Hall terahertz emission is usually based on the inverse orbital Hall effect. The pulsed laser induces spin current in the ferromagnetic layer, the spin current is converted into orbital current through the orbital-spin conversion of the ferromagnetic layer, and the orbital current is injected into light metals (e.g. Ti or Mn) with a strong orbital Hall effect and converted into a charge current through the inverse orbital Hall effect of the light metal, thereby generating an orbitronic terahertz signal.

Regardless of whether generating an orbital torque or emitting an orbitronic terahertz signal, the orbital-spin conversion of the ferromagnetic layer is very important. The orbital-spin conversion (L-S) coefficient of the ferromagnetic layer is closely related to the spin-orbit coupling (SOC) of the ferromagnetic layer. Therefore, based on the orbital Hall effect and the inverse orbital Hall effect of light metals (Zr, Ti and Mn), the ferromagnetic layer with a strong L-S coefficient is selected, thereby enhancing the orbital torque and the orbitronic terahertz signal.

In some embodiments of the present disclosure, a composite heterojunction of a non-magnetic material with weak spin-orbit coupling and a ferromagnetic material may be prepared in a magnetron sputtering method, and a terahertz emission source may be constructed based on the inverse orbital Hall effect of the non-magnetic material with weak spin-orbit coupling instead of inserting the heavy metal or the topological insulator on/under the non-magnetic material.

During the construction of the orbitronic terahertz emission source, a monocrystalline substrate, a ferromagnetic material target, a light metal and a protective layer target may be stacked in sequence; the monocrystalline substrate is made of MgO or Al₂O₃; the ferromagnetic material target may be made of any one or more of Co, Fe, Ni, NiFe, CoFeB, or two-dimensional magnetic film material, such as MnBi₂Te₄, Fe₃GeTe₂, Cr₂Ge₂Te₆, Fe₅GeTe₂ or Fe₃GaTe₂, etc., or other magnetic film materials with similar properties; the light metal is any one or more of Zr, Al, Ti, V, Cr, Ru, Mn, Cu, oxides thereof, and nitrides thereof; and the protective layer target is, for example, made of MgO or Al₂O₃.

### Embodiment 7: Preparation of Al₂O₃/Co/Ti/MgO Heterojunction and Detection of Terahertz Emission Signal

### (1) Sample Preparation

A magnetron sputtering device is used to mount Co, Ti and MgO targets on a sputtering target head. An Al₂O₃ substrate is placed on a sample rack, and necessary process parameters are adjusted to realize a film formation.

The reaction parameters include: a substrate temperature, a sputtering atmosphere, and sputtering power, etc. The final optimized conditions are that the substrate temperature is room temperature; the argon flow rate is 20 sccm; the sputtering pressure intensity is 2.5 mTorr; the sputtering powers of Co, Ti and MgO are 30, 30 and 100 W, respectively; by controlling the growth sequence of respective layers, a Co film of a ferromagnetic layer is grown first, then the Ti film of the non-magnetic layer is grown, and finally an MgO protective layer is grown; the thicknesses of Co, Ti and MgO films are controlled to be 2, 4 to 100 and 5 nm, respectively to prepare Al₂O₃/Co (2 nm)/Ti (4-100 nm)/MgO (5 nm) heterojunction (the applicant's experiments at present show that the light metal layer can exhibit the orbital Hall effect at 4 to 100 nm).

### (2) Terahertz Emission Signal Detection

The terahertz emission spectrum with a central wavelength of 800 nm, a pulse duration of 100 fs, an average power of 2 W and a repetition frequency of 80 MHz is used to measure a terahertz emission.

A femtosecond laser beam is divided into pump light and probe light. The pump light excites a sample under normal incidence, and the probe light detects a generated terahertz wave by electro-optical sampling technology.

The ZnTe (110) electro-optic crystal with a thickness of 2 mm is used for detection, and an in-plane magnetic field is applied to the sample for detection. All the measurements are carried out in a dry room temperature environment. By using the femtosecond laser drive, a terahertz emission signal detection is carried out on the ferromagnetic/non-magnetic heterojunction prepared in the present disclosure.

### (3) Comparison of Results

FIG. 12 illustrates a structure design and measurement diagram of Al₂O₃/Co/Ti/MgO heterojunction in Embodiment 7, wherein a terahertz emission signal is detected by a femtosecond laser excitation from a Co side of a ferromagnetic layer.

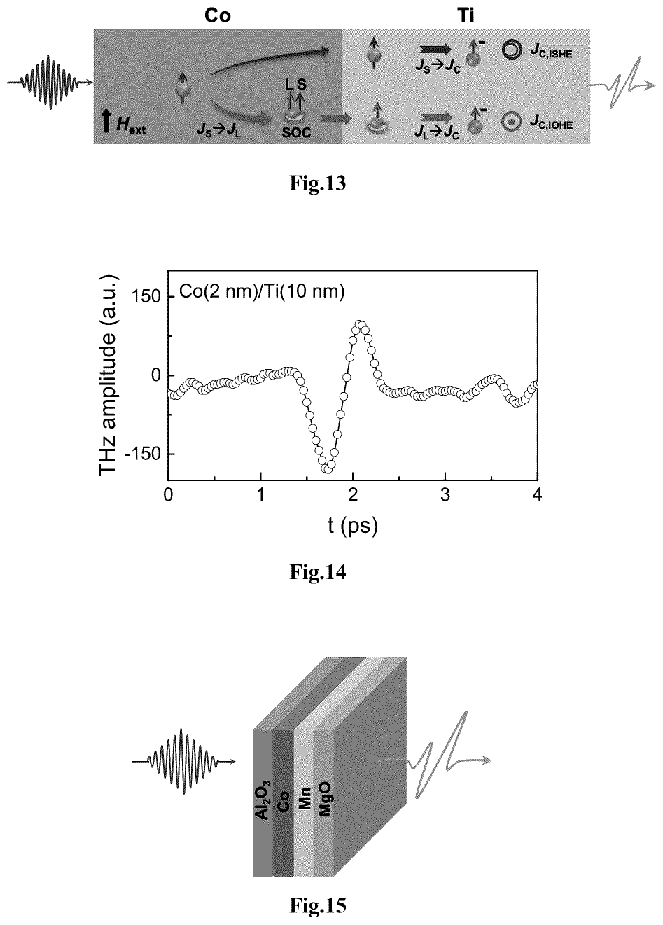

FIG. 13 illustrates a schematic diagram for distinguishing an inverse orbital Hall effect in a composite heterojunction of a ferromagnetic material Co and a weak spin-orbit coupling material Ti in Embodiment 7. An ultrafast (fs) laser excites a spin current in the ferromagnetic Co layer. Due to the strong spin-orbit coupling (SOC) in Co, this spin current is converted into an orbital current. The orbital current then propagates into an adjacent non-magnetic Ti layer, where the inverse orbital Hall effect (IOHE) transforms it into a detectable charge current. By characterizing whether a polarity of a terahertz signal is consistent with a sign of a spin Hall angle of an spin Hall effect or with a sign of a product of an orbital Hall angle and a spin-orbit conversion efficiency of the ferromagnetic layer, it can be proved and distinguished whether a terahertz emission signal in a Co/Ti heterojunction originates from the inverse orbital Hall effect. From the terahertz emission spectrum of Al₂O₃/Co/Ti/MgO heterojunction in FIG. 14, it can be seen that the polarity is consistent with the sign of the product of the orbital Hall angle and the spin-orbit conversion efficiency of the ferromagnetic layer, which indicates that the terahertz emission signal in the Co/Ti heterojunction originates from the inverse orbital Hall effect.

### Embodiment 8: Preparation of Al₂O₃/Co/Mn/MgO Heterojunction and Detection of Terahertz Emission Signal

### (1) Sample Preparation

A magnetron sputtering device is used to mount Co, Mn and MgO targets on a sputtering target head. An Al₂O₃ substrate is placed on a sample rack, and necessary process parameters are adjusted to realize a film formation.

The reaction parameters include: a substrate temperature, a sputtering atmosphere, sputtering power, etc. The final optimized conditions are that the substrate temperature is room temperature; the argon flow rate is 20 sccm; the sputtering pressure intensity is 2.5 mTorr; the sputtering powers of Co, Mn and MgO are 30, 30 and 100 W, respectively; by controlling the growth sequence of respective layers, a Co film of a ferromagnetic layer is grown first, then an Mn film of a non-magnetic layer is grown, and finally an MgO protective layer is grown; the thicknesses of Co, Ti and MgO films are controlled to be 2, 4 to 100 and 5 nm, respectively to prepare Al₂O₃/Co (2 nm)/Mn (4-100 nm)/MgO (5 nm) heterojunction.

### (2) Terahertz Emission Signal Detection

The terahertz emission spectrum with a central wavelength of 800 nm, a pulse duration of 100 fs, an average power of 2 W and a repetition frequency of 80 MHz is used to measure a terahertz emission. A femtosecond laser beam is divided into pump light and probe light. The pump light excites a sample under normal incidence, and the probe light detects a generated terahertz wave by electro-optical sampling technology. The ZnTe (110) electro-optic crystal with a thickness of 2 mm is used for detection, and an in-plane magnetic field is applied to the sample for detection. All the measurements are carried out in a dry room temperature environment. By using the femtosecond laser drive, a terahertz emission signal detection is carried out on the ferromagnetic/non-magnetic heterojunction prepared in the present disclosure.

### (3) Result Test

FIG. 15 illustrates a design and measurement diagram of Al₂O₃/Co/Mn/MgO heterojunction structure in Embodiment 8. A terahertz emission signal is detected by a femtosecond laser excitation from a Co side of a ferromagnetic layer. Similarly, by characterizing whether a polarity of a terahertz signal is consistent with a sign of a spin Hall angle of an inverse spin Hall effect or with a sign of a product of an orbital Hall angle and a spin-orbit conversion efficiency of the ferromagnetic layer, it is proved and distinguished whether a terahertz emission signal in a Co/Ti heterojunction originates from the inverse orbital Hall effect.

### Embodiment 9: Preparation of Al₂O₃/Co/W/Ti/MgO Heterojunction and Detection of Terahertz Emission Signal

### (1) Sample Preparation

A magnetron sputtering device is used to mount Co, Ti, W and MgO targets on a sputtering target head; an Al₂O₃ substrate is placed on a sample rack, and necessary process parameters are adjusted to realize a film formation. The reaction parameters include: a substrate temperature, a sputtering atmosphere, sputtering power, etc. The final optimized conditions are that the substrate temperature is room temperature; the sputtering pressure intensity is 2.5 mTorr; the sputtering powers of Co, Ti, W and MgO are 30, 30, 50 and 100 W, respectively; by controlling the growth sequence of respective layers, a Co film of a ferromagnetic layer is grown first, then a film of heavy metal W or light metal Ti are grown, and finally an MgO protective layer is grown; the thicknesses of Co, Ti, W and MgO films are controlled to be 2, 4 to 100, 2 and 5 nm, respectively to prepare Al₂O₃/Co (2 nm)/W (2 nm)/Ti (4-100 nm)/MgO (5 nm) heterojunction (the applicant's experiments at present show that the light metal layer can exhibit the orbital Hall effect at 4 to 100 nm).

### (2) Preparation of Reference Samples

A magnetron sputtering device is used to mount Co, W, Ti and MgO targets on a sputtering target head; an Al₂O₃ substrate is placed on a sample rack, and necessary process parameters are adjusted to realize a film formation. The reaction parameters include: a substrate temperature, a sputtering atmosphere, sputtering power, etc. The final optimized conditions are that the substrate temperature is room temperature; the sputtering pressure intensity is 2.5 mTorr; the sputtering powers of Co, W, Ti and MgO are 30, 50, 30 and 100 W, respectively; by controlling the growth sequence of respective layers, a Co film of a ferromagnetic layer is grown first, then a film of heavy metal W or light metal Ti is grown, and finally an MgO protective layer is grown; the thicknesses of Co, W, Ti and MgO films are controlled to be 2, 2, 4 and 5 nm, respectively to prepare Al₂O₃/W (2 nm)/MgO (5 nm) and Al₂O₃/Ti (4 nm)/MgO (5 nm) heterojunctions as the reference samples.

### (3) Terahertz Emission Signal Detection

Terahertz emission signal detection: a terahertz emission spectrum with a central wavelength of 800 nm, a pulse duration of 100 fs, an average power of 2 W and a repetition frequency of 80 MHz is used to measure a terahertz emission. A femtosecond laser beam is divided into pump light and probe light. The pump light excites a sample under normal incidence, and the probe light detects a generated terahertz wave by electro-optical sampling technology. The ZnTe (110) electro-optic crystal with a thickness of 2 mm is used for detection, and an in-plane magnetic field is applied to the sample for detection. All the measurements are carried out in a dry room temperature environment. By using the femtosecond laser drive, a terahertz emission signal detection is carried out on the heterojunctions prepared in the present disclosure.

### (4) Result Comparison

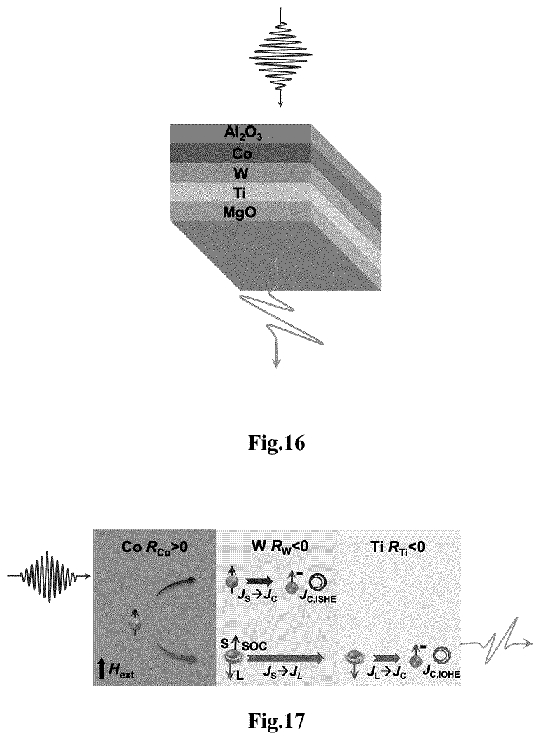

FIG. 16 illustrates a design and measurement diagram of Al₂O₃/Co/W/Ti/MgO heterojunction structure in Embodiment 9. A terahertz emission signal is detected by a femtosecond laser excitation from a Co side of a ferromagnetic layer.

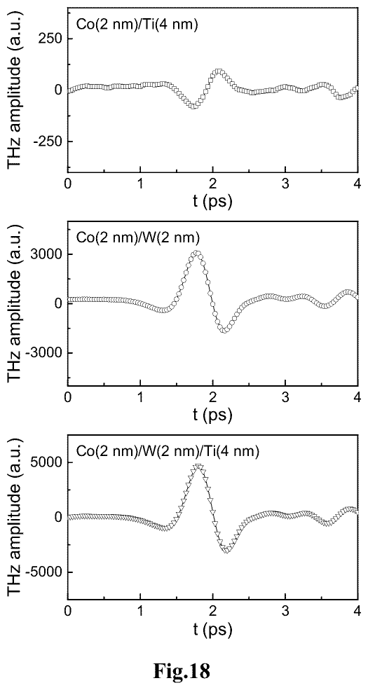

FIG. 17 illustrates a schematic diagram of a mechanism for enhancing an inverse orbital Hall effect of Al₂O₃/Co/W/Ti/MgO heterojunction in Embodiment 9. The femtosecond laser pulse generates a spin current in the ferromagnetic Co layer. This spin current subsequently converts to an orbital current through the combined action of: (1) intrinsic spin-orbit coupling in the ferromagnetic Co layer and (2) the strong spin-orbit coupling of the adjacent W layer. The resulting orbital current then propagates into a non-magnetic Ti layer, where it undergoes conversion into a detectable charge current via the inverse orbital Hall effect. The strong SOC of the heavy metal W insertion layer realizes a conversion from spin current to orbital current, thus providing additional orbital current. FIG. 18 illustrates a terahertz emission spectrogram of Al₂O₃/Co/Ti/MgO, Al₂O₃/Co/W/MgO and Al₂O₃/Co/W/Ti/MgO heterojunctions, which shows that a terahertz signal of Al₂O₃/Co (2 nm)/W (2 nm)/Ti (4 nm)/MgO (5 nm) heterojunction is significantly enhanced relative to that of Al₂O₃/Co (2 nm)/Ti (4 nm)/MgO (5 nm) and Al₂O₃/Co (2 nm)/W (2 nm)/MgO (5 nm) heterojunction.

That is, by comparing the Al₂O₃/Co (2 nm)/W (2 nm)/Ti (4 nm)/MgO (5 nm) heterojunction, the Al₂O₃/W (2 nm)/MgO (5 nm) heterojunction and the Al₂O₃/Ti (4 nm)/MgO (5 nm) heterojunction, it can be found that the insertion of the W layer can enhance the conversion from orbital current to spin current, thus enhancing the terahertz emission.

### Embodiment 10: Preparation of Al₂O₃/Co/W/Mn/MgO Heterojunction and Detection of Terahertz Emission Signal

### (1) Sample Preparation

A magnetron sputtering device is used to mount Co, Mn, W and MgO targets on a sputtering target head; an Al₂O₃ substrate is placed on a sample rack, and necessary process parameters are adjusted to realize a film formation. The reaction parameters include: a substrate temperature, a sputtering atmosphere, sputtering power, etc. The final optimized conditions are that the substrate temperature is room temperature; the sputtering pressure intensity is 2.5 mTorr; the sputtering powers of Co, Mn, W and MgO are 30, 30, 50 and 100 W, respectively; by controlling the growth sequence of respective layers, a Co film of a ferromagnetic layer is grown first, then a film of heavy metal W or light metal Mn is grown, and finally an MgO protective layer is grown; the thicknesses of Co, Mn, W and MgO films are controlled to be 2, 4 to 100, 2 and 5 nm, respectively to prepare Al₂O₃/Co (2 nm)/W (2 nm)/Mn (4-100 nm)/MgO (5 nm) heterojunctions.

### (2) Preparation of Reference Samples

A magnetron sputtering device is used to mount Co, W, Mn and MgO targets on a sputtering target head; an Al₂O₃ substrate is placed on a sample rack, and necessary process parameters are adjusted to realize a film formation. The reaction parameters include: a substrate temperature, a sputtering atmosphere, sputtering power, etc. The final optimized conditions are that the substrate temperature is room temperature; the sputtering pressure intensity is 2.5 mTorr; the sputtering powers of Co, W, Mn and MgO are 30, 50, 30 and 100 W, respectively; by controlling the growth sequence of respective layers, a Co film of a ferromagnetic layer is grown first, then a film of heavy metal W or light metal Mn is grown, and finally an MgO protective layer is grown; the thicknesses of Co, W, Mn and MgO films are controlled to be 2, 2, 4 and 5 nm, respectively to prepare Al₂O₃/W (2 nm)/MgO (5 nm) and Al₂O₃/Mn (4 nm)/MgO (5 nm) heterojunctions as the reference samples.

### (3) Terahertz Emission Signal Detection

A terahertz emission spectrum with a central wavelength of 800 nm, a pulse duration of 100 fs, an average power of 2 W and a repetition frequency of 80 MHz is used to measure a terahertz emission. A femtosecond laser beam is divided into pump light and probe light. The pump light excites a sample under normal incidence, and the probe light detects a generated terahertz wave by electro-optical sampling technology. The ZnTe (110) electro-optic crystal with a thickness of 2 mm is used for detection, and an in-plane magnetic field is applied to the sample for detection. All the measurements are carried out in a dry room temperature environment. By using the femtosecond laser drive, a terahertz emission signal detection is carried out on the heterojunctions prepared in the present disclosure.

### (4) Result Test

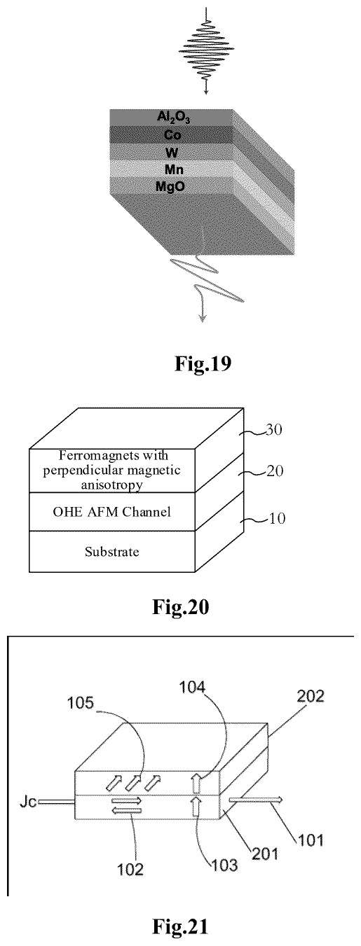

FIG. 19 illustrates a design and measurement diagram of Al₂O₃/Co/W/Mn/MgO heterojunction structure in Embodiment 10. A terahertz emission signal is detected by a femtosecond laser excitation from a Co side of a ferromagnetic layer. Compared with Al₂O₃/Co (2 nm)/Mn (4 nm)/MgO (5 nm) and Al₂O₃/Co (2 nm)/W (2 nm)/MgO ((5 nm), the strong SOC of the heavy metal W insertion layer realizes a conversion from spin current to orbital current, thus providing additional orbital current, so that the orbital Hall effect in the Al₂O₃/Co (2 nm)/W (2 nm)/Mn (4 nm)/MgO (5 nm) heterojunction is significantly enhanced.

As can be seen from the above, by forming a heavy metal layer having strong spin-orbit coupling effect between the ferromagnetic layer and the non-magnetic layer of the ferromagnetic/non-magnetic heterojunction in the orbital device, the inverse orbital Hall effect of the orbital device can be enhanced, thereby improving the efficiency of the device. Such orbital devices based on the inverse orbital Hall effect can be terahertz emission sources, etc., but the present disclosure are not limited to these devices.

The method for enhancing the inverse orbital Hall effect uses the strong spin-orbit coupling effect of heavy metals to enhance conversion from spin current to orbital current, so enhances the inverse orbital Hall effect, and improve the efficiency of the inverse orbital Hall effect. Thus, this method has the advantages of effectively enhancing the inverse orbital Hall effect, with a low cost, high stability, a simple process and being beneficial to industrialization, etc.

The embodiments of the present disclosure further provide a field-free orbital torque device based on an orbital torque antiferromagnetic material, which may be a field-free orbital torque and orbital torque heterojunction devices (or abbreviated as an orbital torque heterojunction device) or a field-free orbital torque and orbital torque magnetic tunnel junction devices (or abbreviated as an orbital torque magnetic tunnel junction device). In the field-free orbital torque device according to the embodiment of the present disclosure, a light metal alloy material (e.g., an antiferromagnetic light metal alloy layer, such as FeMn or FeCr or FeV or [Fe/Mn]ₙ or [Fe/Cr]ₙ or [Fe/V]ₙ, formed by ferromagnetic metals such as Fe, Co or Ni and light metals such as Mn, Cr or V, or Mn₃Sn or Mn₃Ge or Mn₃Ga; or two-dimensional antiferromagnetic film material such as MnPS₃, NiPS₃, FePS₃ or the like, or orbital torque channel layer with similar properties) is used as an antiferromagnetic alloy, which has the orbital Hall effect, and such orbital torque antiferromagnetic material is compounded with a ferromagnetic material to form a heterojunction. The conversion from the charge current to the orbital current is realized based on the orbital Hall effect, and the orbital current enters the ferromagnetic layer and is converted into spin current due to the spin-orbit coupling. Because the antiferromagnetism pins the magnetic moment of the ferromagnetic layer thereon to be deviated from the vertical position to tilt the magnetic moment, the torque generated by the spin current can realize the switching of the magnetic moment of the ferromagnetic layer without an external magnetic field.

FIG. 20 illustrates a structural diagram of a field-free orbital torque and orbital torque heterojunction devices according to an embodiment of the present disclosure. As illustrated in FIG. 20, the heterojunction device includes a monocrystalline substrate 10; an orbital torque antiferromagnetic layer 20 formed on the monocrystalline substrate 10; and a first ferromagnetic layer 30 formed on the orbital torque antiferromagnetic layer.

In which, the orbital torque antiferromagnetic layer is a light metal alloy layer, which is used as an orbital current source to replace the existing orbital current source such as a heavy metal or a topological insulator. More specifically, the orbital torque antiferromagnetic layer is a antiferromagnetic light metal alloy layer or two-dimensional antiferromagnetic film material such as MnPS₃, NiPS₃, FePS₃ or the like, or orbital torque channel layer with similar properties, and the antiferromagnetic light metal alloy layer for example is FeMn or FeCr or FeV or [Fe/Mn]ₙ or [Fe/Cr]ₙ or [Fe/V]ₙ formed by ferromagnetic metals such as Fe, Co or Ni and light metals such as Mn, Cr or V. The first ferromagnetic layer has perpendicular magnetic anisotropy, that is, a ferromagnetic vertical structure layer.

The orbital torque antiferromagnetic layer and the first ferromagnetic layer form an orbital torque antiferromagnetic layer/ferromagnetic layer heterojunction, and the ferromagnetic layer and the antiferromagnetic layer will induce an exchange bias effect, that is, a pinning effect. Therefore, in the embodiment of the present disclosure, the orbital torque antiferromagnetic layer is used to pin the ferromagnetic vertical structure layer (the first ferromagnetic layer), and at the same time, used as an orbital Hall channel to convert the charge current into orbital current, which enters the ferromagnetic layer and is converted into spin current due to the spin-orbit coupling. The field-free orbital torque is achieved by generating a torque effect on the magnetic moment of the first ferromagnetic layer having perpendicular magnetic anisotropy through the spin current.

In the embodiment of the present disclosure, the monocrystalline substrate 10 may be a c-face Al₂O₃ (c-Al₂O₃), SrTiO₃ or MgO substrate, but the present disclosure is not limited thereto. The first ferromagnetic layer may be any one of the ferromagnetic layers made of materials with large spin-orbit conversion coefficients, such as multi-film layers [Co/Pt]ₙ, [Co/Ni]ₙ, [Co/Gd]ₙ and [Co/Tb]ₙ, a multi-film layer of CoFeB/Gd/CoFeB, a single-film layer of CoPt alloy layer, CoNi alloy layer, CoTb alloy layer, CoGd alloy layer, a Mn₃Sn alloy layer, a Mn₃Ge alloy layer, a Mn₃Ga alloy layer, a FePd alloy layer, a FePt alloy layer, or a CoPd alloy layer, or two-dimensional magnetic film material, such as MnBi₂Te₄, Fe₃GeTe₂, Cr₂Ge₂Te₆, Fe₅GeTe₂ or Fe₃GaTe₂, etc., or other magnetic film materials with similar properties, wherein Co/Pt, Co/Ni, Co/Gd and Co/Tb respectively represent a Co/Pt double-film layer (i.e., a double-film layer composed of a Co layer and a Pt layer), a Co/Ni double-film layer (i.e., a double-film layer composed of a Co layer and a Ni layer), a Co/Gd double-film layer (i.e., a double-film layer composed of a Co layer and a Gd layer), and a Co/Tb double-film layer (i.e., a double-film layer composed of a Co layer and a Tb layer); the subscript n represents the number of such double-film layers, and n is an integer equal to or greater than 1; CoFeB is a Co₂₀Fe₆₀B₂₀ single-film layer, the multi-film layer of CoFeB/Gd/CoFeB is a multi-film layer composed of a Co₂₀Fe₆₀B₂₀ layer, a Gd layer, and a Co₂₀Fe₆₀B₂₀ layer. CoPt, CoNi, CoTb and CoGd are all alloy layers.

In this embodiment, the hardware design concepts of the orbital torque heterojunction device based on the orbital torque antiferromagnetic material are:
1) a ferromagnetic vertical structure layer is pinned using an orbital torque antiferromagnetic material (e.g., an antiferromagnetic light metal alloy layer such as FeMn or FeCr or FeV or [Fe/Mn]ₙ or [Fe/Cr]ₙ or [Fe/V]ₙ formed by ferromagnetic metals such as Fe, Co or Ni and light metals such as Mn, Cr or V, or a two-dimensional antiferromagnetic layer such as MnPS₃, NiPS₃ or FePS₃, or an orbital torque channel layer with similar properties), and at the same time, an orbital torque antiferromagnetic material is used as an orbital Hall channel to convert a charge current into orbital current, which enters a ferromagnetic layer and is converted into spin current due to the spin-orbit coupling; the spin current generates a torque effect on the magnetic moment of the first ferromagnetic layer having perpendicular magnetic anisotropy, thereby achieving the field-free orbital torque. On the one hand, the dependence on precious metals is avoided, and on the other hand, the problem of magnetic field interference is solved.
2) From bottom to top, the orbital torque heterojunction device is sequentially provided with a monocrystalline substrate (e.g., c-Al₂O₃, SrTiO₃ or MgO), an orbital torque antiferromagnetic layer (e.g., an antiferromagnetic light metal alloy layer such as FeMn or FeCr or FeV or [Fe/Mn]ₙ or [Fe/Cr]ₙ or [Fe/V]ₙ formed by ferromagnetic metals such as Fe, Co or Ni and light metals such as Mn, Cr or V, or Mn₃Sn or Mn₃Ge or Mn₃Ga, or a two-dimensional antiferromagnetic layer such as MnPS₃, NiPS₃ or FePS₃, or an orbital torque channel layer with similar properties), a ferromagnetic vertical structure layer (i.e., a first ferromagnetic layer, which is a ferromagnetic layer made of materials with large spin-orbit conversion coefficients, such as [Co/Pt]ₙ, [Co/Ni]ₙ, [Co/Gd]ₙ, [Co/Tb]ₙ, CoFeB/Gd/CoFeB, CoPt, CoNi, CoTb, CoGd or CoFeBGd). Regarding the above structure, an orbital torque heterojunction device may be prepared by micro-nanofabrication process.

In the embodiment of the present disclosure, a protective layer may be further formed on the ferromagnetic vertical structure layer to protect the ferromagnetic vertical structure layer from oxidation. As an example, the protective layer may be one or more films made of MgO, Ta, W and SiO₂, but the present disclosure is not limited thereto.

In an embodiment of the present disclosure, a preparation method of an orbital torque heterojunction device based on an orbital torque antiferromagnetic material is as follows:
(1) A magnetron sputtering process is employed to sequentially dispose an orbital torque antiferromagnetic layer and a ferromagnetic vertical structure layer (first ferromagnetic layer) on a monocrystalline substrate.

More specifically, this step includes selecting orbital torque antiferromagnetic layer alloy targets (e.g., an antiferromagnetic light metal alloy layer such as FeMn or FeCr or FeV or [Fe/Mn]ₙ or [Fe/Cr]ₙ or [Fe/V]ₙ formed by ferromagnetic metals such as Fe, Co or Ni and light metals such as Mn, Cr or V, or a two-dimensional antiferromagnetic layer such as MnPS₃, NiPS₃ or FePS₃, or an orbital torque channel layer with similar properties) and ferromagnetic vertical structure layer material targets (e.g., one of the following target combinations: Co and Pt, CoFeB and Gd, Co and Tb, Co and Ni, Co and Gd, CoPt alloy, CoNi alloy, CoTb alloy, CoGd alloy, or other materials with large spin-orbit conversion coefficients, or two-dimensional magnetic film material, such as MnBi₂Te₄, Fe₃GeTe₂, Cr₂Ge₂Te₆, Fe₅GeTe₂ or Fe₃GaTe₂, etc.), using a magnetron sputtering process to adjust necessary process parameters for film formation on the monocrystalline substrate.

During preparation, the reaction parameters may include: a substrate temperature, a sputtering atmosphere, sputtering powers of a ferromagnetic layer and an orbital torque antiferromagnetic layer, etc. As an example, the substrate temperature may be room temperature, the sputtering atmosphere may be Ar gas atmosphere, the pressure intensity may be 3.0 to 5.0 mTorr, and the ferromagnetic layer and the orbital torque antiferromagnetic layer may adopt 50 W DC sputtering power. These reaction parameters are only examples, and the present disclosure is not limited thereto.

Based on the above process, the monocrystalline substrate may be formed with an orbital torque antiferromagnetic layer (e.g., an antiferromagnetic light metal alloy layer such as FeMn or FeCr or FeV or [Fe/Mn]ₙ or [Fe/Cr]ₙ or [Fe/V]ₙ formed by ferromagnetic metals such as Fe, Co or Ni and light metals such as Mn, Cr or V, or a two-dimensional antiferromagnetic layer such as MnPS₃, NiPS₃ or FePS₃, etc.) and a ferromagnetic vertical structure layer (e.g., materials with large spin-orbit conversion coefficients, such as multi-film layers [Co/Pt]ₙ, [Co/Ni]ₙ, [Co/Gd]ₙ or [Co/Tb]ₙ, or CoFeB/Gd/CoFeB, or a single-film layer of CoPt, CoNi, CoTb or CoGd, or two-dimensional magnetic film material, such as MnBi₂Te₄, Fe₃GeTe₂, Cr₂Ge₂Te₆, Fe₅GeTe₂ or Fe₃GaTe₂, etc., or other magnetic film materials with similar properties). In the embodiment of the present disclosure, the ferromagnetic layer may have good perpendicular magnetic anisotropy by adjusting the thickness and the proportion of the ferromagnetic multilayer film or the alloy. FIG. 23 illustrates an example of perpendicular magnetic anisotropy detection results of the ferromagnetic vertical structure layer, and the results in FIG. 23 show that the ferromagnetic vertical structure layer has good perpendicular magnetic anisotropy.

In the existing orbital torque heterojunction device or orbital torque magnetic tunnel junction device based on heavy metal or topological insulator materials, the common orbital torque is realized by pulling away the magnetic moment of the ferromagnetic layer by applying an external magnetic field, and then the spin current generated by the charge current through the heavy metal layer or the topological insulator material produces a torque effect on the magnetic moment of the ferromagnetic layer, so as to realize the orbital torque device. The field-free orbital torque mechanism of the orbital torque heterojunction device obtained in the embodiment of the present disclosure is illustrated in FIG. 21: an antiferromagnetic layer (an antiferromagnetic light metal alloy layer such as FeMn or FeCr or FeV or [Fe/Mn]ₙ or [Fe/Cr]ₙ or [Fe/V]ₙ formed by ferromagnetic metals such as Fe, Co or Ni and light metals such as Mn, Cr or V, or Mn₃Sn or Mn₃Ge or Mn₃Ga, or a two-dimensional antiferromagnetic layer such as MnPS₃, NiPS₃ or FePS₃, or an orbital torque channel layer with similar properties) 201 serves as an orbital Hall channel, and generates a pair of magnetic moments 102 in opposite directions; the antiferromagnetic layer pulls away the magnetic moment 105 of a ferromagnetic vertical structure layer 202 due to the exchange bias effect. Therefore, when charge current J_{C} 101 passes through the antiferromagnetic layer 201, orbital current 103 is generated due to the orbital Hall effect of the orbital torque antiferromagnetic layer, then the orbital current 103 is converted into spin current 104 due to the spin-orbit coupling effect of the ferromagnetic layer, and the spin current 104 has a torque effect on the magnetic moment 105 of the ferromagnetic vertical structure layer, thereby generating a spin-orbit moment and realizing field-free orbital torque.

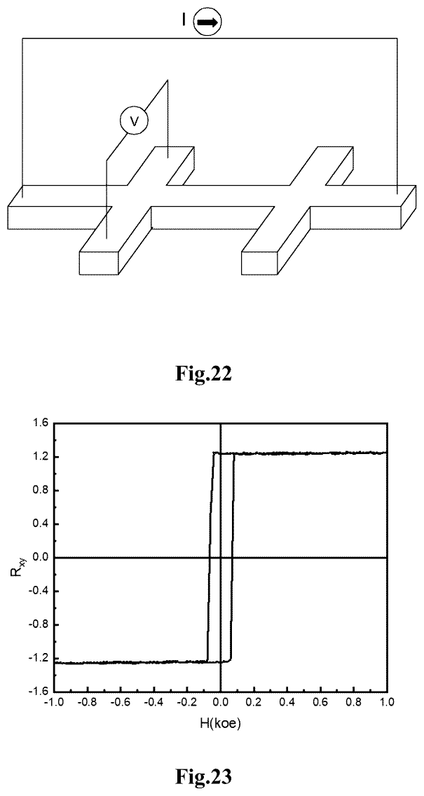

FIG. 22 illustrates a schematic diagram of a field-free orbital torque device according to an embodiment of the present disclosure. By applying pulse current along a transverse axis and reading voltages at both ends of a longitudinal axis, the change of a Hall resistance of the device can be obtained, and the situation of orbital torque can be tested based on the Hall resistance of the device. The test results of the orbital torque switching of the orbital torque heterojunction device show that the device has good perpendicular magnetic anisotropy (PMA), and critical switching current density for realizing switching of the magnetic moment is very low, which shows that the orbital torque efficiency is very high.

The orbital torque heterojunction device provided by the present disclosure can well verify the realization of the field-free orbital torque.

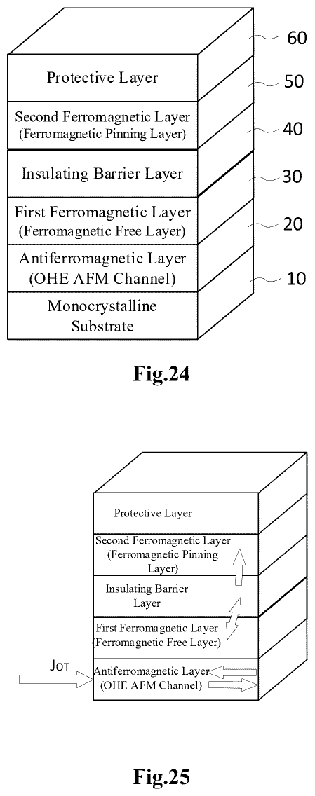

Based on substantially the same mechanism as that of the orbital torque heterojunction device described above, the structure of the orbital torque magnetic tunnel junction device provided by the present disclosure is illustrated in FIG. 24. The orbital torque magnetic tunnel junction device includes not only a monocrystalline substrate 10, an orbital torque antiferromagnetic layer 20 formed on the monocrystalline substrate 10, and a first ferromagnetic layer 30 with perpendicular magnetic anisotropy formed on the orbital torque antiferromagnetic layer, but also an insulating barrier layer 40 formed on the first ferromagnetic layer, and a second ferromagnetic layer 50 formed on the insulating barrier layer 40.

In which, the first ferromagnetic layer serves as a ferromagnetic free layer, and the second ferromagnetic layer serves as a ferromagnetic pinning layer, which is also a ferromagnetic vertical structure layer with perpendicular magnetic anisotropy. The ferromagnetic free layer, the insulating barrier layer and the ferromagnetic pinning layer form a magnetic tunnel junction with a sandwich structure.

Preferably, the orbital torque magnetic tunnel junction device further includes a protective layer 60 formed on the magnetic tunnel junction to protect the ferromagnetic vertical structure layer from oxidation.

The hardware design concept of the orbital torque magnetic tunnel junction device based on the orbital torque antiferromagnetic layer is that an orbital torque antiferromagnetic layer (e.g., an antiferromagnetic light metal alloy layer such as FeMn or FeCr or FeV or [Fe/Mn]ₙ or [Fe/Cr]ₙ or [Fe/V]ₙ formed by ferromagnetic metals such as Fe, Co or Ni and light metals such as Mn, Cr or V, or a two-dimensional antiferromagnetic layer such as MnPS₃, NiPS₃ or FePS₃, or an orbital torque channel layer with similar properties) is used as an orbital Hall channel to convert a charge current into orbital current, which enters a ferromagnetic layer and is converted into spin current due to the spin-orbit coupling; an orbital torque antiferromagnetism layer pins the ferromagnetic free layer thereon by exchange bias, thereby shifting the magnetic moment of the ferromagnetic layer from the perpendicular direction. When no external field is applied, the spin current generates a spin-orbital moment on the ferromagnetic free layer in the sandwich structure of the magnetic tunnel junction to realize a field-free switching of the magnetic moment, thus achieving a tunneling magnetoresistance effect manipulated by the orbital current and realizing the information storage with a low cost, a high density, a high speed and a low power consumption.

In the structure of the orbital torque magnetic tunnel junction device of the embodiment of the present disclosure, the heterojunction of the antiferromagnetic layer and the first ferromagnetic layer will cause an exchange bias effect, that is, a pinning effect, so that the orbital torque antiferromagnetic layer can pin the first ferromagnetic layer. Meanwhile, the orbital torque antiferromagnetic layer serves as an orbital Hall channel (OHE AFM channel), and a sandwich structure of a ferromagnetic layer/an insulating barrier layer/a ferromagnetic layer prepared thereon can generate orbital current based on the orbital Hall effect of the orbital torque antiferromagnetic layer. The orbital current enters the ferromagnetic layer and is converted into spin current due to the spin-orbit coupling, and the spin current generates a spin orbital torque for the ferromagnetic free layer to realize a field-free switching of the magnetic moment. As illustrated in FIG. 25, an orbital torque antiferromagnetic layer (e.g., an antiferromagnetic light metal alloy layer such as FeMn or FeCr or FeV or [Fe/Mn]ₙ or [Fe/Cr]ₙ or [Fe/V]ₙ formed by ferromagnetic metals such as Fe, Co or Ni and light metals such as Mn, Cr or V, or Mn₃Sn or Mn₃Ge or Mn₃Ga, or a two-dimensional antiferromagnetic layer such as MnPS₃, NiPS₃ or FePS₃, or an orbital torque channel layer with similar properties) is used as an orbital Hall channel, and generates a pair of magnetic moments in opposite directions; the antiferromagnetic layer pulls away the magnetic moment of the first ferromagnetic layer due to the exchange bias effect. Therefore, when charge current J_{C} passes through the orbital torque antiferromagnetic layer, orbital current is generated due to the orbital Hall effect of the orbital torque antiferromagnetic layer, then the orbital current enters the ferromagnetic layer and is converted into spin current due to the spin-orbit coupling effect, and the spin current acts as a spin orbital torque on the magnetic moment of the first ferromagnetic layer, thereby realizing field-free orbital torque. The magnetic moment of the free layer and the magnetic moment of the pinning layer form a parallel or antiparallel relationship, thus forming high or low resistance states.

In the embodiment of the present disclosure, the second ferromagnetic layer may be any one of materials with high spin-orbit conversion coefficients, such as multi-film layers [Co/Pt]ₙ, [Co/Ni]ₙ, [Co/Gd]ₙ or [Co/Tb]ₙ, a multi-film layer of CoFeB/Gd/CoFeB, and a single-film layer of CoPt, CoNi, CoTb or CoGd, a Mn₃Sn alloy layer, a Mn₃Ge alloy layer, a Mn₃Ga alloy layer, a FePd alloy layer, a FePt alloy layer, or a CoPd alloy layer, or two-dimensional magnetic film material, such as MnBi₂Te₄, Fe₃GeTe₂, Cr₂Ge₂Te₆, Fe₅GeTe₂ or Fe₃GaTe₂, etc., or other magnetic film materials with similar properties. The material of the second ferromagnetic layer may be the same as or different from that of the first ferromagnetic layer. As an example, the insulating barrier layer may be an insulating oxide such as MgO or TiO₂ or BN or two-dimensional semiconductor.

A preparation method of a field-free orbital torque and orbital torque magnetic tunnel junction device based on an orbital torque antiferromagnetic layer of the present disclosure is as follows:
(1) A magnetron sputtering process is employed to sequentially form an orbital torque antiferromagnetic layer, a ferromagnetic free layer, an insulating barrier layer, a ferromagnetic pinning layer and a protective layer on a monocrystalline substrate (c-Al₂O₃, SrTiO₃ or MgO monocrystalline substrate).

More specifically, this step includes selecting orbital torque antiferromagnetic layer alloy targets (e.g., an antiferromagnetic light metal alloy such as FeMn or FeCr or FeV or [Fe/Mn]ₙ or [Fe/Cr]ₙ or [Fe/V]ₙ formed by ferromagnetic metals such as Fe, Co or Ni and light metals such as Mn, Cr or V, or a two-dimensional antiferromagnetic layer such as MnPS₃, NiPS₃ or FePS₃, or an orbital torque channel layer with similar properties) and ferromagnetic layer material targets (e.g., one of the following target combinations: Co and Pt, CoFeB and Gd, Co and Tb, Co and Ni, Co and Gd, CoPt alloy, CoNi alloy, CoTb alloy, CoGd alloy, or other materials with large spin-orbit conversion coefficients, or two-dimensional magnetic film material, such as MnBi₂Te₄, Fe₃GeTe₂, Cr₂Ge₂Te₆, Fe₅GeTe₂ or Fe₃GaTe₂, etc., or other magnetic film materials with similar properties), insulating barrier layer material targets (e.g., insulating oxides such as MgO or TiO₂ or BN or two-dimensional semiconductor) and protective layer targets (e.g., Ta or W), using a magnetron sputtering process to adjust necessary process parameters for film formation on the monocrystalline substrate, and then preparing an orbital torque magnetic tunnel junction device based on an orbital torque antiferromagnetic layer by micro-nanofabrication process.

During preparation, the reaction parameters may include: a substrate temperature, a sputtering atmosphere, and sputtering powers, etc.

The substrate temperature may be room temperature, the sputtering atmosphere may be Ar gas atmosphere, the pressure intensity for example may be 2.5 to 3.0 mTorr, and the orbital torque antiferromagnetic layer, the ferromagnetic free layer and the ferromagnetic binding layer may adopt 50 W DC sputtering power, while the MgO of the insulating barrier layer may adopt 150 W RF sputtering power. These reaction parameters are only examples, and the present disclosure is not limited thereto.

Based on the above process, an orbital torque antiferromagnetic layer, a ferromagnetic free layer, an insulating barrier layer, a ferromagnetic pinning layer and a protective layer may be formed on a monocrystalline substrate. By adjusting the thickness and composition ratio of each of the ferromagnetic layers (ferromagnetic free layer and ferromagnetic pinning layer), each of the ferromagnetic layers may have good perpendicular magnetic anisotropy.

The orbital Hall effect of the field-free orbital torque and orbital torque magnetic tunnel junction device can also be enhanced by forming a heavy metal layer having strong spin-orbit coupling effect, such as Pt, W, Ta, Gd and Td etc., between the orbital Hall channel (such as an antiferromagnetic layer) and the ferromagnetic layer of of the heterojunction in the orbital torque device based on the orbital Hall effect, thereby the efficiency of the device can be improved.

The orbital torque device (e.g., the orbital torque heterojunction and orbital torque magnetic tunnel junction device) prepared in the present disclosure uses light metal alloy materials to replace heavy metals or topological insulators which have strong spin-orbit coupling effect, and can realize a low cost. In addition, an orbital torque can be realized without an external magnetic field, so that the power consumption is lower and there is no interference of an external magnetic field, thus ensuring better performance. According to the present disclosure, the tunnel junction device may be used for spin orbital torque electronic storage logic devices, etc., so that the storage density can be made higher. In addition, the orbital torque antiferromagnetic material can obtain a smaller switching current density due to a high orbital torque efficiency, so that high-speed writing can be realized.

The orbital torque device with the above structure may be used not only for the spin-orbit torque electronic storage logic devices, but also for electronic devices such as a neural network. That is, these electronic devices include the field-free orbital torque device as mentioned above.

To sum up, the orbital torque magnetic tunnel junction device based on the orbital torque antiferromagnetic layer has many advantages, such as a low cost, a high stability (not easily disturbed by an external magnetic field, and the response to the external magnetic field is insensitive), a simple process and being conducive to industrialization.

In correspondence with the orbital torque device, the present disclosure further provides a method for realizing a field-free orbital torque by using the field-free orbital torque device based on the orbital torque antiferromagnetic material, and the method includes the following steps:
causing charge current to transversely pass through the orbital torque antiferromagnetic layer to generate orbital current through an orbital Hall effect generated by an antiferromagnetic material in the orbital torque antiferromagnetic layer;
causing the orbital current to enter a ferromagnetic layer and be converted into spin current due to the spin-orbit coupling; based on exchange bias effect, tilting the magnetic moment of the ferromagnetic layer by a pinning effect of the orbital torque antiferromagnetic layer on the first ferromagnetic layer without applying an external magnetic field, and generating a torque action on the magnetic moment of the first ferromagnetic layer having perpendicular magnetic anisotropy by the spin current, thereby realizing a field-free orbital torque switching.

It should be clear that the present disclosure is not limited to the specific configurations and processing described above and illustrated in the drawings. For conciseness, the detailed descriptions of the known methods are omitted here. In the above embodiments, several specific steps are described and illustrated as examples. However, the methods and processes of the present disclosure are not limited to the specific steps described and illustrated, and those skilled in the art can make various changes, modifications and additions or change the order of the steps under the spirit of the present disclosure.

In the present disclosure, features described and/or illustrated for one embodiment can be used in the same or similar way in one or more other embodiments, and/or combined with or substituted for features of other embodiments.

Those described above are only the preferred embodiments of the present disclosure, rather than limiting the present disclosure. For those skilled in the art, various modifications and changes can be made to the embodiments of the present disclosure. Any modification, equivalent substitution, improvement, etc. made within the spirit and the principle of the present disclosure should fall within the protection scope of the present disclosure.

1. An orbital torque device based on an orbital Hall effect, comprising a ferromagnetic/non-magnetic heterojunction formed by compounding a ferromagnetic layer and a non-magnetic layer as an orbital current source, wherein the ferromagnetic layer contains a ferromagnetic material, the non-magnetic layer contains a non-magnetic material with weak spin-orbit coupling, wherein the non-magnetic layer is used as an orbital Hall channel to generate orbital current, and the orbital current enters the ferromagnetic layer, so that an orbital torque is generated through an orbital-spin conversion effect of the ferromagnetic layer to realize switching of a magnetic moment.

2. The orbital torque device according to claim 1, further comprising:
a substrate, on which the ferromagnetic/non-magnetic heterojunction is prepared;
wherein the material of the non-magnetic layer as the orbital current source is a light metal material, the ferromagnetic layer comprises a ferromagnetic multi-film layer formed by multiple material layers, a ferromagnetic single-film layer formed by one or more materials or a two-dimensional ferromagnetic material layer, and the ferromagnetic layer has a large orbit-spin conversion coefficient.

3. The orbital torque device according to claim 2, wherein the material of the non-magnetic layer includes one or more of Zr, Ti, Al, Ru, V, Cr, Cu and Mn;
the ferromagnetic single-film layer formed by one or more materials is a CoFeB layer, a Co layer, a Ni layer, a CoNi alloy layer, a CoPt alloy layer, a CoGd alloy layer or a CoTb alloy layer; or a Mn₃Sn alloy layer; or a Mn₃Ge alloy layer; or a Mn₃Ga alloy layer; or a FePd alloy layer; or a FePt alloy layer; or a CoPd alloy layer;
the multi-film layer formed by the multiple material layers is a multi-film layer of CoFeB/Gd/CoFeB, a multi-film layer composed of one or more Co/Pt double-film layers, a multi-film layer composed of one or more Co/Gd double-film layers, a multi-film layer composed of one or more Co/Tb double-film layers or a multi-film layer composed of one or more Co/Ni double-film layers; wherein, the multi-film layer of CoFeB/Gd/CoFeB is composed of a CoFeB layer, a Gd layer and a CoFeB layer; the Co/Pt double-film layer is composed of a Co layer and a Pt layer; the Co/Gd double-film layer is composed of a Co layer and a Gd layer; the Co/Tb double-film layer is composed of a Co layer and a Tb layer; and the Co/Ni double-film layer is composed of a Co layer and a Ni layer;
the two-dimensional ferromagnetic material is MnBi₂Te₄, Fe₃GeTe₂, Cr₂Ge₂Te₆, Fe₅GeTe₂ or Fe₃GaTe₂.

4. The orbital torque device according to claim 1, wherein the non-magnetic layer is prepared by a magnetron sputtering process;
when the ferromagnetic layer is a single-film layer or a multi-film layer, each of the film layers is prepared by a magnetron sputtering process; when the ferromagnetic layer is a two-dimensional ferromagnetic material, the two-dimensional ferromagnetic material is prepared by a magnetron sputtering process, CVD/CVT or mechanical exfoliation.

5. The orbital torque device according to claim 1, wherein the orbital torque device is a field-free orbital torque device based on an orbital Hall effect; the field-free orbital torque device comprises:
a monocrystalline substrate;
an orbital torque antiferromagnetic layer formed on the monocrystalline substrate; and
a first ferromagnetic layer formed on the orbital torque antiferromagnetic layer;
wherein the orbital torque antiferromagnetic layer is an antiferromagnetic alloy layer containing an antiferromagnetic layer, or a light metal material or a two-dimensional antiferromagnetic layer, the first ferromagnetic layer has perpendicular magnetic anisotropy, the orbital torque antiferromagnetic layer and the first ferromagnetic layer form an orbital torque antiferromagnetic layer/ferromagnetic layer heterojunction, and the orbital torque antiferromagnetic layer is used to pin the first ferromagnetic layer to tilt the magnetic moment, and is used as an orbital Hall channel to convert a charge current into an orbital current, and then the orbital current is converted into a spin current in the first ferromagnetic layer, so that the spin current exerts orbital torque on the first ferromagnetic layer with perpendicular magnetic anisotropy to realize field-free orbital torque switching of the magnetic moment.

6. The orbital torque device according to claim 5, wherein the field-free orbital torque device is an orbital torque magnetic tunnel junction device for field-free orbital torque switching;
the first ferromagnetic layer is used as a ferromagnetic free layer; the field-free orbital torque device and orbital torque magnetic tunnel junction device further comprises:
an insulating barrier layer formed on the first ferromagnetic layer; and
a second ferromagnetic layer formed on the insulating barrier layer and used as a ferromagnetic pinning layer having perpendicular magnetic anisotropy;
the ferromagnetic free layer, the insulating barrier layer and the ferromagnetic pinning layer form the orbital torque magnetic tunnel junction with a sandwich structure.

7. The orbital torque device according to claim 5, wherein,
the first ferromagnetic layer is one of: a multi-film layer composed of one or more Co/Pt double-film layers, a multi-film layer composed of one or more Co/Ni double-film layers, a multi-film layer composed of one or more Co/Gd double-film layers, a multi-film layer composed of one or more Co/Tb double-film layers, a multi-film layer of CoFeB/Gd/CoFeB, a CoNi alloy layer, a CoPt alloy layer, a CoGd alloy layer or a CoTb alloy layer, or a Mn₃Sn alloy layer; or a Mn₃Ge alloy layer; or a Mn₃Ga alloy layer; or a FePd alloy layer; or a FePt alloy layer; or a CoPd alloy layer, or a two-dimensional magnetic film material MnBi₂Te₄, Fe₃GeTe₂, Cr₂Ge₂Te₆, Fe₅GeTe₂ or Fe₃GaTe₂;
the second ferromagnetic layer is one of: a multi-film layer composed of one or more Co/Pt double-film layers, a multi-film layer composed of one or more Co/Ni double-film layers, a multi-film layer composed of one or more Co/Gd double-film layers, a multi-film layer composed of one or more Co/Tb double-film layers, a multi-film layer of CoFeB/Gd/CoFeB, a CoNi alloy layer, a CoPt alloy layer, a CoGd alloy layer, or a CoTb alloy layer, or a Mn₃Sn alloy layer; or a Mn₃Ge alloy layer; or a Mn₃Ga alloy layer; or a FePd alloy layer; or a FePt alloy layer; or a CoPd alloy layer, or a two-dimensional magnetic film material MnBi₂Te₄, Fe₃GeTe₂, Cr₂Ge₂Te₆, Fe₅GeTe₂ or Fe₃GaTe₂;
wherein the Co/Pt double-film layer is composed of a Co layer and a Pt layer; the Co/Ni double-film layer is composed of a Co layer and a Ni layer; the multi-film layer of CoFeB/Gd/CoFeB is composed of a CoFeB layer, a Gd layer and a CoFeB layer, the Co/Gd double-film layer is composed of a Co layer and a Gd layer, and the Co/Tb double-film layer is composed of a Co layer and a Tb layer.

8. The orbital torque device according to claim 5, wherein the antiferromagnetic alloy layer containing a light metal is an antiferromagnetic light metal alloy layer formed by a ferromagnetic metal and a light metal;
the antiferromagnetic light metal alloy layer includes FeMn, FeCr, FeV, [Fe/Mn]ₙ or [Fe/Cr]ₙ or [Fe/V]ₙ; and the two-dimensional antiferromagnetic layer includes MnPS₃, NiPS₃ or FePS₃.

9. The orbital torque device according to claim 1, wherein the orbital torque device is an orbital Hall nano oscillator;
the non-magnetic layer is a light metal, oxide of the light metal, nitride of the light metal, an antiferromagnetic light metal alloy layer formed by a ferromagnetic metal and a light metal, or a two-dimensional antiferromagnetic layer.

10. The orbital torque device according to claim 9, wherein
the light metal includes one or more of Zr, Al, Ti, Mn, Ru, V, Cr, and Cu;
the antiferromagnetic light metal alloy layer includes FeMn, FeCr, FeV, [Fe/Mn]ₙ, [Fe/Cr]ₙ or [Fe/V]ₙ;
the two-dimensional antiferromagnetic layer includes MnPS₃, NiPS₃ or FePS₃;
the ferromagnetic layer is one of: a multi-film layer composed of one or more Co/Pt double-film layers, a multi-film layer composed of one or more Co/Ni double-film layers, a multi-film layer composed of one or more Co/Gd double-film layers, a multi-film layer composed of one or more Co/Tb double-film layers, a multi-film layer of CoFeB/Gd/CoFeB, a CoNi alloy layer, a CoPt alloy layer, a CoGd alloy layer or a CoTb alloy layer, or a Mn₃Sn alloy layer; or a Mn₃Ge alloy layer; or a Mn₃Ga alloy layer; or a FePd alloy layer; or a FePt alloy layer; or a CoPd alloy layer, or a two-dimensional magnetic film material MnBi₂Te₄, Fe₃GeTe₂, Cr₂Ge₂Te₆, Fe₅GeTe₂ or Fe₃GaTe₂; wherein the Co/Pt double-film layer is composed of a Co layer and a Pt layer; the Co/Ni double-film layer is composed of a Co layer and a Ni layer; the multi-film layer of CoFeB/Gd/CoFeB is composed of a CoFeB layer, a Gd layer and a CoFeB layer, the Co/Gd double-film layer is composed of a Co layer and a Gd layer, and the Co/Tb double-film layer is composed of a Co layer and a Tb layer.

11. The orbital torque device according to claim 1, further comprising a protective layer prepared on the ferromagnetic/non-magnetic heterojunction.

12. The orbital torque device according to claim 1, wherein a heavy metal layer having strong spin-orbit coupling is formed between the ferromagnetic layer and the non-magnetic layer of the ferromagnetic/non-magnetic heterojunction, and the heavy metal layer having strong spin-orbit coupling is used to enhance the orbital Hall effect.

13. A method for realizing a field-free orbital torque switching based on an orbital torque device, wherein the orbital torque device comprises: a monocrystalline or polycrystalline substrate; an orbital torque antiferromagnetic layer formed on the monocrystalline or polycrystalline substrate; and a first ferromagnetic layer formed on the orbital torque antiferromagnetic layer; wherein the orbital torque antiferromagnetic layer is an antiferromagnetic alloy layer containing a light metal material, the first ferromagnetic layer has perpendicular magnetic anisotropy, and the orbital torque antiferromagnetic layer and the first ferromagnetic layer form an orbital torque antiferromagnetic layer/ferromagnetic layer heterojunction;
the method comprises the steps of:
causing charge current to transversely pass through the orbital torque antiferromagnetic layer, so as to generate orbital current through an orbital Hall effect generated by an antiferromagnetic material in the orbital torque antiferromagnetic layer;
converting the orbital current into spin current through the orbital torque antiferromagnetic layer, tilting a magnetic moment of the first ferromagnetic layer through a pinning effect of the antiferromagnetic layer on the first ferromagnetic layer without applying an external magnetic field, and generating a torque action on the magnetic moment of the first ferromagnetic layer having perpendicular magnetic anisotropy by the spin current, thereby realizing a field-free orbital torque switching.

14. A method for enhancing efficiency of an orbitronic device based on orbital Hall effect or inverse orbital Hall effect, comprising:
preparing, on a substrate, a ferromagnetic/non-magnetic heterojunction formed by compounding a ferromagnetic layer and a non-magnetic layer as an orbital current source, wherein the ferromagnetic layer contains a ferromagnetic material, the non-magnetic layer contains a non-magnetic material with weak spin-orbit coupling; and
constructing the orbitronic device based on orbital Hall effect or inverse orbital Hall effect of the non-magnetic material with weak spin-orbit coupling;
wherein the non-magnetic layer as the orbit current source is made of light metal, and the ferromagnetic layer comprises a multi-film layer formed by multiple material layers, a single-film layer formed by a plurality of materials or a two-dimensional ferromagnetic material layer, and the ferromagnetic layer has an orbit-spin conversion coefficient larger than a preset value.

15. The method according to claim 14, wherein the orbitronic device is an orbital torque electronic storage device, an orbital torque magnetic tunnel junction device or an orbital Hall nano oscillator device based on orbital Hall effect, or an orbitronic terahertz emission source based on inverse orbital Hall effect.

16. The method according to claim 14, wherein preparing, on a substrate, a ferromagnetic/non-magnetic heterojunction formed by compounding a ferromagnetic layer and a non-magnetic layer as an orbital current source comprises: preparing, on a substrate, a ferromagnetic/non-magnetic heterojunction including a ferromagnetic layer, heavy a metal layer having strong spin-orbit coupling and a non-magnetic layer as an orbital current source, the heavy metal layer having strong spin-orbit coupling is used to enhance the orbital Hall effect or the inverse orbital Hall effect.

17. A orbitronic device based on an inverse orbital Hall effect, comprising a ferromagnetic/non-magnetic heterojunction formed by compounding a ferromagnetic layer and a non-magnetic layer as an orbital current source, wherein the ferromagnetic layer contains a ferromagnetic material, the non-magnetic layer contains a non-magnetic material with weak spin-orbit coupling, and the non-magnetic material is a light metal; and
the orbitronic terahertz emission source is constructed based on the inverse orbital Hall effect of the non-magnetic material with weak spin-orbit coupling.

18. The orbitronic device based on the inverse orbital Hall effect according to claim 17, wherein, the orbitronic device based on the inverse orbital Hall effect is a terahertz emission source;
the terahertz emission source comprises a monocrystalline substrate, the ferromagnetic layer, the non-magnetic layer and a protective layer which are sequentially stacked;
the ferromagnetic material layer is made of any one or more of Co, Fe, Ni, NiFe, CoFeB, and two-dimensional ferromagnetic material layer, the two-dimensional ferromagnetic material layer including MnBi₂Te₄, Fe₃GeTe₂, Cr₂Ge₂Te₆, Fe₅GeTe₂ or Fe₃GaTe₂;
the light metal layer is made of any one or more of Zr, Al, Ti, Ru, V, Cr, Mn, Cu, oxides thereof and nitrides thereof.

19. The orbitronic device based on the inverse orbital Hall effect according to claim 17, wherein a heavy metal layer having strong spin-orbit coupling is formed between the ferromagnetic layer and the non-magnetic layer of the ferromagnetic/non-magnetic heterojunction, and the heavy metal layer having strong spin-orbit coupling is used to enhance the inverse orbital Hall effect.

20. The orbitronic device based on the inverse orbital Hall effect according to claim 19, wherein the orbitronic device comprises:
a heterojunction including a ferromagnetic layer, a heavy metal layer, a light metal layer and a protective layer prepared on a monocrystalline substrate by a magnetron sputtering method;
wherein the monocrystalline substrate is Al₂O₃ or MgO;
wherein the ferromagnetic layer is a film made of any one of Co, Fe, Ni, NiFe and CoFeB;
wherein the heavy metal layer is a film made of any one of W, Pt, Ta, Au and Pd;
wherein the light metal layer is a film made of any one of Al, Ti, V, Zr, Ru, Cr, Mn and Cu.
